(19) United States
(12) Patent Application Publication
(10) Pub. No.: US 2012/0057385 A1
(43) Pub. Date: Mar. 8, 2012

(54) POWER CONTROL CIRCUIT

(76) Inventors: Yen-Wei Hsu, Taipei (TW); Whei-Chyou Wu, Fremont, CA (US)

(21) Appl. No.: 12/876,179

(22) Filed: Sep. 6, 2010

(51) Int. Cl. H02M 7/537; H03K 7/08

(52) U.S. Cl. 363/131; 332/109

(57) ABSTRACT

This invention relates to a power control circuit, and, an inventive PWM controller, switching circuit, high voltage discharge circuit and magnetic amplifier are also introduced and used to construct the power control circuit. The power control circuit has featured power saving and wide frequency band.

### FIELD OF INVENTION

This invention relates to a power control circuit, and, an inventive PWM controller, switching circuit, high voltage discharge circuit and magnetic amplifier are also introduced and used to construct the power control circuit. The power control circuit has featured power saving and wide frequency band.

### BACKGROUND INFORMATION

The background includes information related to the present invention and the background information begins with the definitions of positive and negative differential resistors or respectively in short as PDR and NDR. The serially coupling of the PDR and NDR functioning as damper will also be discussed in the background information section.

### INTRODUCTION

Referring to [4], [38], [47, Vol. 1 Chapter 50] and [26, Page 402], the nonlinear system response produces many un-modeled effects: jump or singularity, bifurcation, rectification, harmonic and subharmonic generations, frequency-amplitude relationship, phase-amplitude relationship, frequency entrainment, nonlinear oscillation, stability, modulations (amplitude, frequency, phase) and chaoes. In the nonlinear analysis fields, it needs to develop the mathematical tools for obtaining the resolution of nonlinearity. Up to now, there exists three fundamental problems which are self-adjoint operator, spectral (harmonic) analysis, and scattering problems, referred to [36, Chapter 4.], [43, Page 303], [39, Chapter X], [4], Chapter XI], [40, Chapter XIII], [28] and [38, Chapter 7.].

There are many articles involved the topics of the nonlinear spectral analysis and reviewed as the following sections. The first one is the nonlinear dynamics and self-excited or self-oscillation systems. It provides a profound viewpoint of the non-linear dynamical system behaviors, which are duality of second-order systems, self-excitation, orbital equivalence or structural stability, bifurcation, perturbation, harmonic balance, transient behaviors, frequency-amplitude and phase-amplitude relationships, jump phenomenon or singularity occurrence, frequency entrainment or synchronization, and so on. In particular, the self-induced current (voltage) or electricity generation appears if applying to the Liénard system.

### Positive and Negative Differential Resistors (PDR, NDR)

More inventively, due to observing the positive and negative differential resistors properties qualitatively, we introduce the Cauchy-Riemann equations, [3], Part 1, 2], [48], [11], [45] and [3], for describing a system impedance transient behaviors and particularly in some sophisticated characteristics system parameterization by one dedicated parameter ω. Consider the impedance z in specific variables (i,v) complex form of

z=F(i,v)+jG(i,v) (1)

where i, v are current and voltage respectively. Assumed that the functions F(i,v) and G(i,v) are analytic in the specific domain. From the Cauchy-Riemann equations, there have as following

$$\begin{matrix}\frac{\partial F}{\partial i} = \frac{\partial G}{\partial v} & ( 2 ) \\ and & \\ \frac{\partial F}{\partial v} = \frac{\partial G}{\partial i} & ( 3 )\end{matrix}$$

where in these two functions there exists one relationship based on the Hilbert transforms [19, Page 296] and [22, Page 5]. In other words, the functions F(i,v) and G(i,v) do not be obtained individually. Using the chain rule, equations (2) and (3) are further obtained

$$\begin{matrix}\frac{\partial F}{\partial ω} \frac{d ω}{d i} = \frac{\partial G}{\partial ω} \frac{d ω}{d v} & ( 4 ) \\ and & \\ \frac{\partial F}{\partial ω} \frac{d ω}{d v} = - \frac{\partial G}{\partial ω} \frac{d ω}{d i} & ( 5 )\end{matrix}$$

where the parameter ω could be the temperature field T, magnetic field flux intensity B, optical field intensity I, in the electric field for examples, voltage v, current i, frequency f or electrical power P, in the mechanical field for instance, magnitude of force F, and so on. Let the terms

$$\begin{matrix}\{ \begin{matrix}\frac{d ω}{d v} > 0 \\ \frac{d ω}{d i} > 0\end{matrix} & ( 6 ) \\ or & \\ \{ \begin{matrix}\frac{d ω}{d v} < 0 \\ \frac{d ω}{d i} < 0\end{matrix} & ( 7 )\end{matrix}$$

be non-zero and the same sign. Under the same sign conditions as equation (6) or (7), from equation (4) to equation (5),

$$\begin{matrix}\frac{\partial F}{\partial ω} > 0 & ( 8 ) \\ and & \\ \frac{\partial F}{\partial ω} < 0 & ( 9 )\end{matrix}$$

should be held simultaneously. From the viewpoint of making a power source, the simple way to perform equations (6) and (7) is using the pulse-width modulation (PWM) method. The further meaning of equations (6) and (7) is that using the variable frequency ω in pulse-width modulation to current and voltage is the most straightforward way, i.e.,

$$\{ \begin{matrix}\frac{d ω}{d v} \neq 0 \\ \frac{d ω}{d i} \neq 0\end{matrix}$$

After obtaining the qualitative behaviors of equation (8) and equation (9), also we need to further respectively define the quantative behaviors of equation (8) and equation (9). Intuitively, any complete system with the system impedance equation (1) could be analogy to the simple-parallel oscillator as the series oscillator which correspondent 2^{nd}-order differential equation is as (12) or (15) respectively. Referring to [47, Vol 2, Chapter 8, 9, 10, 11, 22, 23], [18, Page 173], [5, Page 181], [24, Chapter 10] and [13, Page 951-968], let the current iₗ and voltage v_{C} be replaced by x, y respectively. From the Kirchhoff's Law, this simple oscillator is expressed as the form of

$$\begin{matrix}L \frac{d x}{d t} = y & ( 10 ) \\ C \frac{d y}{d t} = - x + {F}_{p} ( y ) & ( 11 )\end{matrix}$$

or in matrix form

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}0 \\ \frac{{F}_{p} ( y )}{C}\end{matrix} ] \qquad ( 12 )$$

where the function Fₚ (y) represents the generalized Ohm's law and for the single variable case, Fₚ(x) is the real part function of the impedance function equation (1), the “p” in short, is a “parallel” oscillator. Furthermore, equation (12) is a Liénard system. If taking the linear from of Fₚ(y),

Fₚ(y)=Ky

and K>0, it is a normally linear Ohm's law. Also, the states equation of a simple series oscillator is

$$\begin{matrix}L \frac{d x}{d t} = y - {F}_{s} ( x ) & ( 13 ) \\ C \frac{d y}{d t} = - x & ( 14 )\end{matrix}$$

in the matrix form,

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}- \frac{{F}_{s} ( x )}{L} \\ 0\end{matrix} ] \qquad ( 15 )$$

The i_{C}, vₗ have to be replaced by x, y respectively. The function Fₛ(x) indicates the generalized Ohm's law and (15) is the Liénard system too. Again, considering one system, let L,C be to one, then the system (15) becomes the form of

$$[ \begin{matrix}\frac{d x}{d t} \\ \frac{d y}{d t}\end{matrix} ] = [ \begin{matrix}y - {F}_{s} ( x ) \\ - x\end{matrix} ] \qquad ( 16 )$$

To obtain the equilibrium point of the system (15), setting the right hand side of the system (16) is zero

$$\{ \begin{matrix}y - {F}_{s} ( 0 ) = 0 \\ - x = 0\end{matrix}$$

where F₃ (0) is a value of the generalized Ohm's law at zero. The gradient of (16) is

$$[ \begin{matrix}- {F}_{s}^{′} ( 0 ) & 1 \\ - 1 & 0\end{matrix} ]$$

Let the slope of the generalized Ohm's law Fₛ′(0) be a new function as fₛ(0)

fₛ(0)≡Fₛ′(0)

the correspondent eigenvalues λ_{1,2}^{s} are as

$${λ}_{1 , 2}^{s} = \frac{1}{2} [ - {f}_{s} ( 0 ) \pm \sqrt{{( {f}_{s} ( 0 ) )}^{2} - 4} ]$$

Similarly, in the simple parallel oscillator (12),

fₚ(0)≡Fₚ″(0)

the equilibrium point of (12) is set to (Fₚ(0),0) and the gradient of (12) is

$$[ \begin{matrix}0 & 1 \\ - 1 & {f}_{p} ( 0 )\end{matrix} ]$$

the correspondent eigenvalues λ_{1,2}^{p} are

$${λ}_{1 , 2}^{p} = \frac{1}{2} ( {f}_{p} \pm \sqrt{{( {f}_{p} ( 0 ) )}^{2} - 4} )$$

The qualitative properties of the systems (12) and (15), referred to [13] and [24], are as the following:
1. fₛ(0)>0, or fₚ(0)<0, its correspondent equilibrium point is a sink.
2. fₛ(0)<0, or fₚ(0)>0, its correspondent equilibrium point is a source.
   Thus, observing previous sink and source quite different definitions, if the slope value of impedance function Fₛ(x) or Fₚ(y), fₛ(x) or fₚ(y) is a positive value

Fₛ′(x)=fₛ(x)>0 (17)

or

Fₚ′(y)=fₚ(y)>0 (18)
it is the name of the positive differential resistivity or PDR. On contrary, it is a negative differential resistivity or NDR.

Fₛ′(x)=fₛ(x)<0 (19)

or

Fₚ′(y)=fₚ(y)<0 (20)
3. if fₛ(0)=0, or fₚ(0)=0, its correspondent equilibrium point is a bifurcation point, referred to [25, Page 433], [26, Page 26] and [24, Chapter 10] or fixed point, [2, Chapter 1, 3, 5, 6], or singularity point, [6], [1, Chapter 22, 23, 24].

Fₛ′(x)=fₛ(x)=0 (21)

or

Fₚ′(y)=fₚ(y)=0 (22)

Liénard Stabilized Systems

Taking the system equation (12) or equation (15) is treated as a nonlinear dynamical system analysis, we can extend these systems to be a classical result on the uniqueness of the limit cycle, referred to [1, Chapter 22, 23, 24], [26, Page 402-407], [37, Page 253-260], [24, Chapter 10, 11] and many articles [30], [21], [34], [32], [33], [17], [10], [44], [9], [16], [8], [12] for a dynamical system as the form of

$$\{ \begin{matrix}\frac{d x}{d t} = y - F ( x ) \\ \frac{d y}{d t} = - g ( x )\end{matrix} \qquad ( 23 )$$

under certain conditions on the functions F and g or its equivalent form of a nonlinear dynamics

$$\frac{{d}^{2} x}{d {t}^{2}} + f ( x ) \frac{d x}{d t} + g ( x ) = 0 \qquad ( 24 )$$

where the damping function ƒ(x) is the first derivative of impedance function F(x) with respect to the state x

f(x)=F′(x) (25)

Based on the spectral decomposition theorem [25, Chapter 7], the damping function has to be a non-zero value if it is a stable system. The impedance function is a somehow specific pattern,

y=F(x) (26)

From equation (23), equation (24) and equation (25), the impedance function F(x) is the integral of damping function ƒ(x) over one specific operated domain x>0 as

F(x)=∫₀^{x}f(s) (27)

Under the assumptions that F, g∈C¹(R), F and g are odd functions of x, F(0)=0, F′(0)<0, F has single positive zero at x=a, and F increases monotonically to infinity for x≧a as x→∞, it follows that the Liénard's system equation (23) has exactly one limit cycle and it is stable. The initial condition of the (27) is extended to an arbitrary setting as

F(x)=∫ₐ^{x}f(ζ)dζ (28)

where a∈R. We conclude that an adaptive-dynamic damping function F(x) with the following properties:
1. The damping function is not a constant. At the interval,

α≦a
the impedance function F(x) is

F(x)<0
The derivative of F(x) with respect to x is

F′(x)=f(x)≧0 (29)
one part is a PDR as defined (17) or (18) and

F′(x)=f(x)<0 (30)
another is a NDR as defined (19) or (20), hold simultaneously. Which means that the impedance function F(x) has the negative and positive slopes at the interval α≦a.
2. Following the Liénard theorem [37, Page 253-260], [24, Chapter 10, 11], [26, Chapter 8] and the correspondent theorems, corollaries and lemma, we can further conclude that one stabilized system which has at least one limit cycle, all solutions of the system (23) converge to this limit cycle even asymptotically stable periodic closed orbit. In fact, this kind of system construction can be realized a stabilized system in Poincaré sense [37, Page 253-260], [24, Chapter 10, 11], [18, Chapter 1, 2, 3, 4], [5, Chapter 3].

Furthermore, one nonlinear dynamic system is as the following form of

$$\begin{matrix}\frac{{d}^{2} x}{d {t}^{2}} + ɛ f ( x , y ) \frac{d x}{d t} + g ( x ) = 0 & ( 31 ) \\ or & \\ \{ \begin{matrix}\frac{d x}{d t} = y - ɛ F ( x , y ) \\ \frac{d y}{d t} = - g ( x )\end{matrix} & ( 32 ) \\ where & \\ f ( x , y ) & ( 33 )\end{matrix}$$

is a nonzero and nonlinear damping function,

g(x) (34)

is a nonlinear spring function, and

F(x,y) (35)

is a nonlinear impedance function also they are differentiable. If the following conditions are valid
1. there exists a>0 such that f(x,y)>0 when \sqrt{x²+y²}≦a.
2. f(0,0)<0 (hence f(x,y)<0 in a neighborhood of the origin).
3. g(0)=0, g(x)>0 when x>0, and g(x)<0 when x<0.
4. G(x)=∫₀^{x}g(u)du→∞ as x→∞.
   then (31) or (32) has at least one periodic solution.

### Frequency-Shift Damping Effect

Referring to the books [3, p 313], [39, Page 10-11], [28, Page 13] and [45, page 171-174], we assume that the function is a trigonometric Fouries series generated by a function g(t)∈L(I), where g(t) should be bounded and the unbounded case in the book [45, page 171-174] has proved, and L (I) denotes Lebesgue-integrable on the interval I, then for each real β, we have

$$\begin{matrix}{lim}_{ω \to ∞} {\int }_{I} g ( t ) {e}^{i ( ω t + β )} d t = 0 & ( 36 ) \\ where & \\ {e}^{i ( ω t + β )} = cos ( ω t + β ) + i sin ( ω t + β ) & \end{matrix}$$

the imaginary part of (36)

$${lim}_{ω \to ∞} {\int }_{I} g ( t ) sin ( ω t + β ) d t = 0 \qquad ( 37 )$$

and real part of (36)

$${lim}_{ω \to ∞} {\int }_{I} g ( t ) cos ( ω t + β ) d t = 0 \qquad ( 38 )$$

are approached to zero as taking the limit operation to infinity, ω→∞, where equation (37) or (38) is called “Riemann-Lebesgue lemma” and the parameter ω is a positive real number. If g(t) is a bounded constant and ω>0, it is naturally the (37) can be further derived into

$$\vert {\int }_{a}^{b} {e}^{i ( ω t + β )} d t \vert = \vert \frac{{e}^{i a ω} - {e}^{i b ω}}{ω} \vert \leq \frac{2}{ω}$$

where [a, b]∈I is the boundary condition and the result also holds if on the open interval (a,b). For an arbitrary positive real number ∈>0, there exists a unit step function s(t), referred to [3, p 264], such that

$${\int }_{I} \vert g ( t ) - s ( t ) \vert d t < \frac{ɛ}{2}$$

Now there is a positive real number M such that if ω≧M,

$$\vert {\int }_{I} s ( t ) {e}^{i ( ω t + β )} d t \vert < \frac{ɛ}{2} \qquad ( 39 )$$

holds. Therefore, we have

$$\vert {\int }_{I} g ( t ) {e}^{i ( ω t + β )} d t \vert \leq \vert {\int }_{I} ( g ( t ) - s ( t ) ) {e}^{i ( ω t + β )} d t \vert + \vert {\int }_{I} s ( t ) {e}^{i ( ω t + β )} d t \vert \leq {\int }_{I} \vert g ( t ) - s ( t ) \vert d t + \frac{ɛ}{2} < \frac{ɛ}{2} + \frac{ɛ}{2} = ɛ \qquad ( 40 )$$

i.e., (37) or (38) is verified and hold.

According to the Riemann-Lebesgue lemma, the equation (36) or (38) and (37), as the frequency ω approaches to ∞ which means

$$\begin{matrix}ω ≫ 0 & ( 41 ) \\ then & \\ {lim}_{ω \to ∞} {\int }_{I} g ( t ) {e}^{i ( ω t + β )} d t = 0 & \end{matrix}$$

The equation (41) is a foundation of the energy dissipation and it is called the “positive damping effect” for dissipating the action energy. For removing any destructive energy component, (41) tells us the truth whatever the frequencies are produced by the harmonic and subharmonic waveforms and completely “damped” out by the ultra-high frequency modulation.

On contrary, we take the parameter ω from a large number shifting to near zero,

$${lim}_{ω \to 0} {\int }_{I} g ( t ) {e}^{i ( ω t + β )} d t = P \qquad ( 42 )$$

the amplitude of (42) P becomes a non-zero and significant value, this is called the “negative damping effect” for gaining the reaction energy or energy amplification.

Observing (41), the function g(t) is an amplitude of power which is the amplitude-frequency dependent and seen the book [26, Chapter 3, 4, 5, 6]. It means if the higher frequency ω produced, the more g(t) is attenuated. When moving the more higher frequency, the energy of (41) is the more rapidly diminished. We conclude that a large part of the power has been dissipated to the excited frequency ω fast drifting across the board of each reasonable resonant point, rather than transferred into the thermal energy (heat). After all, applying the energy to a system periodically causes the ω to be drifted continuously from low to very high frequencies for the energy absorbing and dissipating. Again removing the energy, the frequency rapidly returns to the nominal state. It is a fast recovery feature. That is, this system can be performed and quickly returned to the initial states periodically.

As the previous described, realized that the behavior of the frequency getting high as increasing the amplitude of energy and vice versa, expressed as the form of

ω=ω(g(t)) (43)

The amplitude-frequency relationship as (43) which induces the adaptation of system. It means which magnitude of the energy produces the corresponding frequency excitation like as a complex damper function (33).

### Magnetic Amplifier (MagAmp)

Referred to [46], [7], [15], [29], [27, Chapter 8], [23, Page 261-274], all devices using flux in magnetic cores as a gating or control medium may be classed as magnetic amplifiers.

### Algebra of Inductances

Referred to the book [20, Chapter 1], the magnetic response of a media can be obtained as the following

B=μH (44)

where H and B and μ are magnetic intensity (Henry), magnetic flux density (Gauss) and permeability of the magnetic material respectively. In addition, if applying to one transformer, its permeability μ depends on the specific gap size between transformer cores internally and almost is not a constant.

Furthermore, referred to [27, Chapter 8], [35, Page 325-327], [14, Chapter IV], [23, Page 261-274], the power is defined by

$$\begin{matrix}\frac{d W}{d t} = I ( N \frac{d φ}{d t} ) \\ = SNI \frac{d B}{d t}\end{matrix} \qquad ( 45 )$$

and changing the variable from I to H which is a magnetic intensity which has N turns and carries a current I through the length l core,

$$H = ( \frac{N}{l} ) I$$

then (45) becomes the form of

$$\begin{matrix}\frac{d W}{d t} = ( Sl ) ( \frac{N}{l} ) I \frac{d B}{d t} \\ = τ H \frac{d B}{d t}\end{matrix} \qquad ( 46 )$$

where the S, N are the cross-section area and number of turns respectively, the volume τ of the magnetic core which length is l, is defined by

τ=Sl

and the magnetic induction B is

$$B = \frac{φ}{S} \qquad ( 47 )$$

where φ is the magnetic flux. Taking the integral to (46), the total energy of the magnetic core during one cycle around the hysteresis loop is obtained as

W=τ [symbol] HdB (48)

For delivering the maximizing energy (48) in this core, i.e.,

Wₘₐₓ=Max(τ [symbol] HdB) (49)

As the B reaches to the Bₘₐₓ in the hysteresis loop, which means this magnetic core is saturated. That is,

B=Bₘₐₓ

and

H=Hₘₐₓ

which means the hysteresis curve becomes a closed rectangular loop or square B-H loop and the maximized total energy (49) in the volume τ core is

Wₘₐₓ=τBₘₐₓHₘₐₓ

This is a saturable reactor.

### Analysis of MagAmp

Referred to [42, Page 85-90], based on the Faraday's law,

$$e = N \frac{d φ}{d t} \qquad ( 50 )$$

where e is the instantaneous voltage, N is the turns, φ is the total flux (in maxwells) respectively. Also, the e.m.f. is

Eₐ=4.44(BAfNₐ)(10⁸) (51)

where Eₐ is the applied voltage (rms) and has to be equal to the back e.m.f. generated by changing flux in the cores, that is,

Eₐ=k₂Nₐ (52)

B is the maximum induction or flux desity (in gauss) defined in (47) and then flux is

φ=BA

A is the core area (cm²), f is the applied frequency of supply and Nₐ is the turns respectively. Given a number n, and hence the internal resistance rₐ is defined as

$$n = \frac{R}{{r}_{a}} \qquad ( 53 )$$

where the R is the resistance of an external load. In other word, the total resistance of this magamp is

$${R}_{a} = ( 1 + \frac{1}{n} ) R \qquad ( 54 )$$

For determining the internal resistance rₐ, let the resistance of the winding be, where ρ is the resistivity of the winding conductive cable, l is the total length of winding cable and a is the cross-sectional area of the cable, then,

$$\begin{matrix}{r}_{a} = \frac{ρ l}{a} & ( 55 ) \\ Furthermore , & \\ l = {N}_{a} {t}_{a} & \end{matrix}$$

where tₐ is the length of the mean turn.

$$a = \frac{{A}_{a}}{{SN}_{a}}$$

where Aₐ is total available area and S is the shape factor. Once the core has be chosen, we conclude the form of rₐ

$${r}_{a} = {k}_{1} {N}_{a}^{2}$$

$$also$$

$${r}_{a} = {t}_{a} ( \frac{ρ S}{{A}_{a}} ) {N}_{a}^{2}$$

that is, the constant k₁ of the core is then obtained as the form of

$${k}_{1} = ( \frac{ρ S}{{A}_{a}} ) {t}_{a}$$

Let the e.m.f be eₒ and equal to the control input voltage,

$${e}_{o} = {i}_{o} {R}_{o} + {L}_{o} \frac{d {i}_{o}}{d t} + \frac{{N}_{o}}{{10}^{8}} \frac{d}{d t} ( {φ}_{2} - {φ}_{1} )$$

where the first term iₒRₒ is dorp voltage on the resistance Rₒ,

$${e}_{o} = \frac{{N}_{a}}{{N}_{o}} {R}_{o} {i}_{a} + \frac{{N}_{a}}{{N}_{o}} {L}_{o} \frac{d {i}_{a}}{d t} + \frac{{N}_{o}}{{10}^{8}} \frac{d}{d {i}_{a}} ( {φ}_{2} - {φ}_{1} ) \frac{d {i}_{a}}{d t}$$

$$and$$

$$\frac{d}{d {i}_{a}} ( {φ}_{2} - {φ}_{1} ) = ( \frac{{R}_{a}}{4 f {N}_{a}} ) ( {10}^{8} )$$

$$i . e . , \\ {e}_{o} = \frac{{N}_{a}}{{N}_{o}} {R}_{o} {i}_{a} + [ \frac{{N}_{a}}{{N}_{o}} {L}_{o} + ( \frac{{N}_{o} {R}_{a}}{4 f {N}_{a}} ) ] \frac{d {i}_{a}}{d t}$$

the solution is

$$\begin{matrix}{i}_{a} = \frac{{e}_{o}}{{R}_{o}} \frac{{N}_{a}}{{N}_{o}} ( 1 - {e}^{- \frac{t}{T}} ) \\ where & ( 56 ) \\ T = \frac{{L}_{o}}{{R}_{o}} + \frac{1}{4 f} \frac{{R}_{a} {N}_{a}^{2}}{{R}_{o} {N}_{o}^{2}} & ( 57 )\end{matrix}$$

The current gain is

$$\begin{matrix}{G}_{c} = \frac{{i}_{a}}{{i}_{o}} \\ = \frac{{N}_{o}}{{N}_{a}}\end{matrix} \qquad ( 58 )$$

and the power gain is

$$\begin{matrix}{G}_{p} = \frac{{i}_{a}^{2} {R}_{a}}{{i}_{o}^{2} {R}_{o}} \\ = \frac{{N}_{o}^{2} {R}_{a}}{{N}_{a}^{2} {R}_{o}}\end{matrix} \qquad ( 59 )$$

Assumed the value of Rₐ

$${R}_{a} = ( 1 + n ) ρ ( \frac{{t}_{a}}{{A}_{a}} ) {N}_{a}^{2}$$

and also Rₒ to be the value of

$${R}_{o} = ρ ( \frac{{t}_{o}}{{A}_{o}} ) {N}_{o}^{2}$$

Applying to the power gain (59), the power gain becomes

$${G}_{p} = ( 1 + n ) \frac{{t}_{a} {A}_{o}}{{t}_{o} {A}_{a}} \qquad ( 60 )$$

i.e., the gain value is proportional to core size and the number n is defined (53). From (57), the time constant, in terms of power gain (59), becomes

$$\begin{matrix}T = \frac{{L}_{o}}{{R}_{o}} + \frac{{G}_{p}}{4 f} \\ = \frac{{L}_{o}}{{R}_{o}} + \frac{( 1 + n )}{4 f} \frac{{t}_{a} {A}_{o}}{{t}_{o} {A}_{a}}\end{matrix}$$

### Effect of Self-Excitation

As the DC control winding is assisted by a feedback from all or part of the rectified output current, this winding provides a self-excited or positive feedback. Under this condition, the total DC control ampere-turns will be Nₒiₒ+N_{f}i_{f} and equivalent to the total AC ampere-turns such that

iₐNₐ=Nₒiₒ+N_{f}i_{f}

i.e.,

Nₒiₒ=iₐNₐ−N_{f}i_{f}

that is,

iₒNₒ=iₐNₐ(1−α) (61)

and the current gain (58) becomes as

$$\frac{{i}_{a}}{{i}_{o}} = \frac{{N}_{o}}{{N}_{a}} ( \frac{1}{1 - α} ) \qquad ( 62 )$$

where the value of α is a feedback factor

$$α = \frac{{i}_{f} {N}_{f}}{{i}_{a} {N}_{a}} \qquad ( 63 )$$

The iₐ in (56) has been modified as, neglecting the leakage,

$${i}_{a} = \frac{{e}_{o}}{{R}_{o}} \frac{{N}_{o}}{{N}_{a} ( 1 - α )} ( 1 - {e}^{- \frac{t}{T}} ) \\ where \\ T = \frac{{G}_{p} ( 1 - α )}{4 f} \qquad ( 64 )$$

Comparing (56) to (64), the output current iₛ is increased in the ratio of

$$\frac{1}{1 - α} \qquad ( 65 )$$

and the power gain increased also in the ratio of (65).

For any close loop the impedance function can be written in the complex form having real and imaginary parts shown as the equation (1), and the following three equations (6), (7) and (21) hold simultaneously. Equations (6), (7) and (21) are the intrinsic properties in any closed loop. Equations (6) and (7) are respectively defined as positive differential resistance (or PDR in short) and negative differential resistance (or NDR in short) in the present invention, and, equation (21) is defined as pure resistance. A device having PDR or NDR is respectively called a PDR device or a NDR device in the present invention. A device having pure resistance is called a pure resistor in the present invention. Revealed in the “Positive and Negative Differential Resistances” in the background information section, the PDR and NDR devices can vary with temperature field T, magnetic field such as magnetic flux intensity B, optical field such as optical field intensity I, electric field such as voltage v, current i, frequency f, electrical power P, acoustic field, mechanical field such as magnitude of force F, vibration force or any combinations of them listed above. And, the pure resistor is irrelevant to temperature field T, magnetic field such as magnetic flux intensity B, optical field such as optical field intensity I, electric field such as voltage v, current i, frequency f, electrical power P, acoustic field, mechanical field such as magnitude of force F, or vibration force.

For any closed loop, obviously, the two equations (6) and (7) can be respectively carried out by a PDR device and a NDR device, and the two simultaneously held equations (6) and (7) can be carried out by a PDR device and a NDR device electrically connected in series.

Any closed loop without the PDR and NDR devices those intrinsic properties described by the (6) and (7) can not be realized, which means that the loop's dynamic behavior is much more suppressed, concealed and difficult to be observable. In other words, a loop's dynamic behavior will be much more significantly observable if the loop has the PDR and NDR devices.

The impedance function equation (1) expressed in spectrum domain is true for any closed loop and tells that the loop in nature includes unlimited harmonic, sub-harmonic, super-harmonic, intermediate harmonic components and combinations of them in a multi-band waveforms with very broad bandwidth. But without frequency responding device in the loop some or all of the waveform components may be concealed, suppressed or in insignificantly observable mode. A loop having at least a PDR device and a NDR device electrically connected in series can have significant, more observable and enlarged harmonic, sub-harmonic, super-harmonic and intermediate harmonic components which will modulate all together to produce more significantly observable multi-band waveforms with considerably broad bandwidth.

The mathematical equation (41) has been proved always true for any g(t) in 1902. The integral part of the equation can be the form or expression of electrical power if it is interpreted into electrical domain and tells that it includes amplitude, frequency and phase. By taking frequency limit operation on the equation its integral (or summation) is approaching to zero, which can be interpreted that the electrical power is dissipated if frequency shifted to higher enough. Please note that the result after summation of the equation (41) is not function of time, which means that the dissipation of electrical power is not done by a given time internal instead the dissipation of electrical power is done by frequency shifting at an instant time. It means that the dissipation of electrical power by frequency-shifting can be done in a very effective and quick way. The “dissipation of electrical power” means that the electrical power in terms of current and voltage can be transformed into another energy forms such as RF, magnetic field, optical field, heat, etc, or any combinations of them. For example, if frequencies in and out of CPU respectively are around 20 kHz and 3 GHz so that a lot of the electrical power will be transformed into heat under this high frequency shifting, which explains why CPU needs a strong fan.

Revealed in the frequency-shift damping effect section of the background information, a PDR device and a NDR device electrically connected in series has frequency-shift damping effect which can perform higher-frequency shifting resulting in the dissipation of electrical power. And further, as earlier revealed, the PDR, and NDR devices are field-interactable so that the dissipation of electrical power of a loop can be controlled by fields interactions listed above. This is a new method of the dissipation of electrical power of any closed loop by ultra-high frequency modulation revealed by the present invention. A damper comprises a PDR device and a NDR device electrically connected in series.

### REFERENCES

[1] Nicholas Minorsky. Nonlinear oscillations. Van Nostrand, New York., http://www.alibris.com, 1962.
[2] Alberto Abbondandolo. Morse Theory for Hamiltonian Systems. CRC Press., http://www.crcpress.com/, 2000.
[3] Tom M. Apostol. Mathematical Analysis. Addison-Wesley Publishing Company., http://www.aw-bc.com/, 2nd edition, 1975.
[4] V. I. Arnold. Ordinary Differential Equations. MIT Press., http://www.mitpress.com/, 1973.
[5] V. I. Arnold. Geometrical Methods in the Theory of Ordinary Differential Equations. Springer-Verlag., http://www.springer-ny.com/, 2nd edition, 1988.
[6] V. I. Arnold. Theory of Singularities and its Applications, volume 1. American Mathematical Society., http://www.ams.org/, 2nd edition, 1990.
[7] George M. Attura. Magnetic Amplifier Engineering. McGrall-Hill Book Company, http://www.alibris.com, 1959.
[8] J. Balakrishnan. A geometric framework for phase synchronization in coupled noisy nonlinear systems. Physical Review E, 73:036206, 2006.
[9] Timoteo Carletti and Gabriele Villari. A note on existence and uniqueness of limit cycles for li 'enard systems, 2003.
[10] V. K. Chandrasekar, M. Senthilvelan, and M. Lakshmanan. An unusual li 'enard type nonlinear oscillator with properties of a linear harmonic oscillator, 2004.
[11] E. T. Copson. An introduction to the theory of functions of a complex variable. Oxford University Press., http://www.amazon.com/, 4th edition, 1948.
[12] M. C. Cross, A. Zumdieck, Ron Lifshitz, and J. L. Rogers. Synchronization by nonlinear frequency pulling. Physical Review Letters, 93:224101, 2004.
[13] R. Wong F. Cuker. The Collected Papers of Stephen Smale., volume 3. Singapore University Press., http://www.worldscibooks.com/mathematics, 2000.
[14] Fred Alan Fish. Fundamental Principles of Electric and Magnetic Circuits. BiblioBazaar, LLC, http://www.bibliobazaar.com/opensource, 2008.
[15] William A. Geyger. Magnetic-Amplifier Circuits. McGrall-Hill Book Company, http://www.alibris.com, 1954.
[16] H. Giacomini and S. Neukirch. On the number of limit cycles of the liénard equation, 1997.
[17] Jaume Gine and Maite Grau. A note on “relaxation oscillators with exact limit cycles”, 2005.
[18] John Guckenheimer and Philip Holmes. Nonlinear Oscillations, Dynamical Systems, and Bifurcations of Vector Fields. Springer-Verlag., http://www.springer-ny.com/, 1997.
[19] Ernest A. Guillemin, editor. Synthesis of Passive Networks: Theory and Methods Appropriate to the Realization and Approximation Problems. John Wiley and Sons., 1957.
[20] Alberto Passos Guimaraes and I. S. Oliveira. Magnetism and Magnetic Resonance in Solids. A John Wiley and Sun, Inc., http://www.wiley.com, 1998.
[21] Edward H. Hellen and Matthew J. Lanctot. Nonlinear damping of the lc circuit using anti-parallel diodes, 2006.
[22] Arthur R. Von Hippel. Dielectrics and Waves. A John Wiley & Sun, Inc., http://www.wiley.com, 1954.
[23] Arthur Von Hippel. Dielectric Materials and Applications. Artech House Publishers., http://www.artechhouse.com, 1995.
[24] Morris W. Hirsh and Stephen Smale. Differential Equations, Dynamical Systems and Linear Algebra. Academic Press., http://www.academicpress.com/, 1974.
[25] Thomas J. R. Hughes. Jerrold E. Marsden. Mathematical Foundations of Elasticity. Prentice-Hall, Inc., http://www.doverpublications.com/, 1984.
[26] D. W. Jordan and Peter Smith. Nonlinear Ordinary Differential Equations. Oxford University Press., http://www.oup.co.uk/academic/, 3rd edition, 1999.
[27] H. W. Katz. Solid State Magnetic and Dielectric Devices. A John Wiley & Sun, Inc., http://www.wiley.com, 1959.
[28] Yitzhak Katznelson. An Introduction to Harmonic Analysis. Cambridge University Press, http://www.amazon.com/, 2nd edition, 1968.
[29] David L. Lafuze. Magnetic Amplifier Analysis. John Wiley & Sons, Inc., http://www.alibris.com, 1962.
[30] Alexandra S. Landsman and Ira B. Schwartz. Predictions of ultra-harmonic oscillations in coupled arrays of limit cycle oscillators, 2006.
[31] Serge Lang. Complex Analysis. Springer-Verlag., http://www.springer.de/phy/books/ssp, 4th edition, 1999.
[32] Jose-Luis Lopez and Ricardo Lopez-Ruiz. The limit cycles of lienard equations in the strongly non-linear regime, 2002.
[33] Jose-Luis Lopez and Ricardo Lopez-Ruiz. Approximating the amplitude and form of limit cycles in the weakly non-linear regime of lienard systems, 2006.
[34] Jose-Luis Lopez and Ricardo Lopez-Ruiz. The limit cycles of lienard equations in the weakly nonlinear regime, 2006.
[35] Paul Lorrain and Dale R. Corson. Electromagnetic Fields and Waves. W.H. Freeman and Company, 2nd edition, 1970.
[36] Peter J. Olver. Applications of Lie Groups to Differential Equations. Springer-Verlag., http://www.springer-ny.com/, 1993.
[37] Lawrence Perko. Differential Equations and Dynamical Systems. Springer-Verlag, New York, Inc., http://www.springer-ny.com, 3rd edition, 2000.
[38] Jerrold E. Marsden. Ralph Abraham. Foundations of Mechanics. Perseus Publishing., http://www. perseusbooksgroup.com/front.html, 2nd edition, 1984.
[39] Michael Reed and Barry Simon. Methods of Modern Mathematical Physics: Fourier Analysis, Self-Adjointness., volume 2. Academic Press., http://www.academicpress.com, 1975.
[40] Michael Reed and Barry Simon. Methods of Modern Mathematical Physics: Analysis of Operators, volume 4. Academic Press., http://www.academicpress.com, 1978.
[41] Michael Reed and Barry Simon. Methods of Modern Mathematical Physics: Scattering Theory, volume 3. Academic Press., http://www.academicpress.com, 1979.
[42] J. H. REYNER. The Magnetic Amplifier. A. W. Duncan, http://www.alibris.com, 1950.
[43] George F. Simmons. Introduction to Topology and Modern Analysis. McGRAW-HILL Inc., http://books.mcgraw-hill.com, 1963.
[44] Ali Taghavi. On periodic solutions of lienard equations, 2004.
[45] E. T. Whittaker and G. N. Watson. A Course of Modern Analysis. Cambridge Mathematical Library., http://www.cambridge.org, 4th edition, 1927.
[46] Herbert Horace Woodson. Magnetic-Amplifier Analysis Using a Generalized Model For the Saturable Reactor Core. PhD thesis, Massachusetts Institute of Technology, May 1956.
[47] Matthew Sands. WRichard P. Feynman, Robert B. Leighton. Feynman Lectures On Physics: The Complete And Definitive Issue, volume 3. Addison Wesley Publishing Company., http://www.aw-bc.com, 2nd edition, 1964.
[48] A. David Wunsch. Complex Variables with Applications. Addison-Wesley Publishing Company Inc., http://www.awbc.com/, 1983.

### SUMMARY OF THE INVENTION

It's a first objective to provide two new PWM controllers for controlling the on/off switchings of a switch.

It's a second objective to provide switching circuits based on three different PWM controllers and the switching circuits have featured power saving and wide band.

It's a third objective to provide high voltage discharge circuits based on the switching circuits and the high voltage discharge circuits have featured power saving and wide band, and the high voltage discharge circuits are good drivers for ionization, welding, waste powdering and electrolyzing.

It's a fourth objective to provide a new magnetic amplifier. It's a fifth objective to provide a plurality of the magnetic amplifiers coupled in series.

It's a sixth objective to provide a plurality of the magnetic amplifiers coupled with the inventive switching circuits and the high voltage discharge circuits.

### BRIEF DESCRIPTION OF THE DRAWINGS

FIG. 1 has shown a flow chart used to describe a first PWM controller;

FIG. 2 has shown a flow chart used to describe a second PWM controller;

FIG. 3a has shown a first switching circuit constructed by the first PWM controller;

FIG. 3b has shown the first switching circuit of FIG. 3a of which the first switch is a power transistor, the damper is realized by a PDR device and a NDR device electrically connected in series, the action/reaction isolation device is realized by a capacitor and the coupler is realized by a transformer formed by a third coil and a fourth coil.

FIG. 3c has shown the first switching circuit of FIG. 3b of which the capacitor, the PDR device and the NDR device are subtituted by an energy discharge capacitor;

FIG. 3d has shown an embodiment of a first high voltage discharge circuit based on the first switching circuit;

FIG. 3e has shown another embodiment of a first high voltage discharge circuit based on the first switching circuit;

FIG. 3f has shown the first high voltage discharge circuit of FIG. 3d of which a device is disposed under the influence of the high voltage built at the open discharge gap, and the device can be an ion-release device, a welding device or a waste;

FIG. 3g has shown the first high voltage discharge circuit of FIG. 3e of which a device is disposed under the influence of the high voltage built at the open discharge gap, and the device can be an ion-release device, a welding device or a waste;

FIG. 3h has shown the first high voltage discharge circuit of FIG. 3d for driving an electrolyzer;

FIG. 3i has shown the first high voltage discharge circuit of FIG. 3e for driving an electrolyzer;

FIG. 4a has shown a second switching circuit constructed by the second PWM controller;

FIG. 4b has shown the second switching circuit of FIG. 4a of which the first switch and the second switch are power transistors, the damper is realized by a PDR device and a NDR device electrically connected in series, the action/reaction isolation device is realized by a capacitor and the coupler is realized by a transformer formed by a third coil and a fourth coil.

FIG. 4c has shown the second switching circuit of FIG. 4b of which the capacitor, the PDR device and the NDR device are subtituted by an energy discharge capacitor;

FIG. 4d has shown an embodiment of a second high voltage discharge circuit based on the second switching circuit;

FIG. 4e has shown another embodiment of a second high voltage discharge circuit based on the second switching circuit;

FIG. 4f has shown the second high voltage discharge circuit of FIG. 4d of which a device is disposed under the influence of the high voltage built at the open discharge gap, and the device can be an ion-release device, a welding device or a waste;

FIG. 4g has shown the second high voltage discharge circuit of FIG. 4e of which a device is disposed under the influence of the high voltage built at the open discharge gap, and the device can be an ion-release device, a welding device or a waste;

FIG. 4h has shown the second high voltage discharge circuit of FIG. 4d for driving an electrolyzer;

FIG. 4i has shown the second high voltage discharge circuit of FIG. 4e for driving an electrolyzer;

FIG. 5a has shown the third switching circuit constructed by the third PWM controller;

FIG. 5b has shown the third switching circuit of FIG. 5a of which the first switch is a power transistor, the damper is realized by a PDR device and a NDR device electrically connected in series and the action/reaction isolation device is realized by a capacitor.

FIG. 5c has shown the third switching circuit of FIG. 5b of which the capacitor, the PDR device and the NDR device are subtituted by an energy discharge capacitor;

FIG. 5d has shown an embodiment of a third high voltage discharge circuit based on the third switching circuit;

FIG. 5e has shown another embodiment of a third high voltage discharge circuit based on the third switching circuit;

FIG. 5f has shown the third high voltage discharge circuit of FIG. 5d of which a device is disposed under the influence of the high voltage built at the open discharge gap, and the device can be an ion-release device, a welding device or a waste;

FIG. 5g has shown the third high voltage discharge circuit of FIG. 5e of which a device is disposed under the influence of the high voltage built at the open discharge gap, and the device can be an ion-release device, a welding device or a waste;

FIG. 5h has shown the third high voltage discharge circuit of FIG. 5d for driving an electrolyzer;

FIG. 5i has shown the third high voltage discharge circuit of FIG. 5e for driving an electrolyzer;

FIG. 6a has shown a conventional magnetic amplifier;

FIG. 6b has shown an invention magnetic amplifier of which the reaction is used as the ac input;

FIG. 6c has shown the reaction mentioned in FIG. 6b is further described by “ac Lenz current flowing through reaction circuit”;

FIG. 6d has shown two inventive magnetic amplifiers;

FIG. 6e has shown an embodiment of the coupling of two inventive magnetic amplifiers;

FIG. 6f has shown a filter is added to the embodiment of FIG. 6e;

FIG. 6g has shown a NDR device is added to the embodiment of FIG. 6f;

FIG. 6h has shown the coupling of the two magnetic amplifiers of FIG. 6g of which the rectifier is a Cockcroft-Walton generator and the damper is realized by a PDR device and a NDR device electrically connected in series;

FIG. 6i has shown two magnetic amplifers embedded with the first switching circuit of FIG. 3a;

FIG. 6j has shown two reaction circuits in parallel built in the first switching circuit of FIG. 3a and ac Lenz current through each reaction circuit flows through each ac input coil of two magnetic amplifers;

FIG. 6k has shown three magnetic amplifiers coupled in series;

FIG. 6l has shown an ac output of an magnetic amplifer is frequency-shifted to charge a buffer or a battery;

FIG. 6m has shown two ac input coils respectively of two magnetic amplifiers are in parallel in a same reaction circuit of a first switching circuit;

FIG. 6n has shown an embodiment of a first switching circuit containing a plurality of coils in series with each other;

FIG. 6o has shown two coils coupled in series in an embodiment of a first switching circuit and the two coils are respectively the dc signal input coils of two magnetic amplifiers; and

FIG. 7 has shown an eddy current cancelling circuit for solving eddy current of a static magnet.

### DETAILED DESCRIPTION OF THE INVENTION

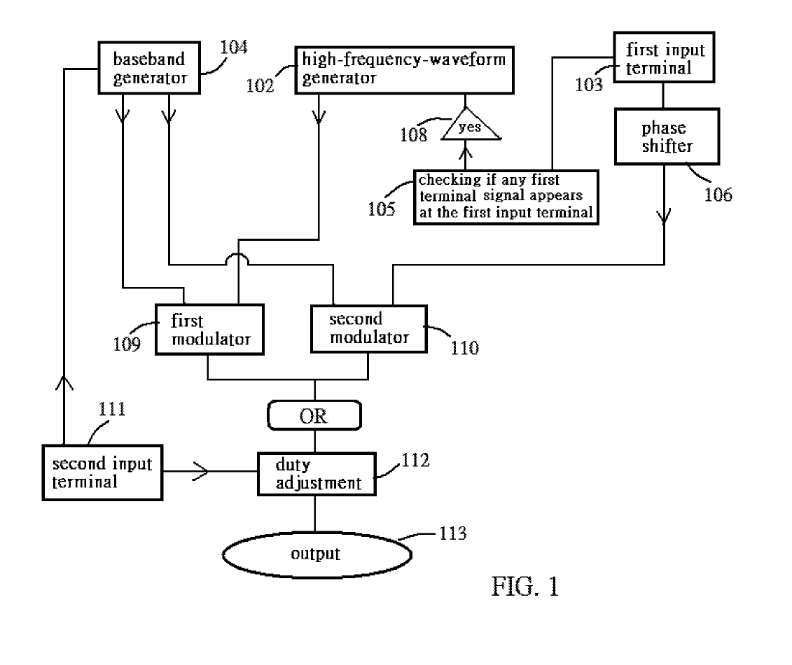

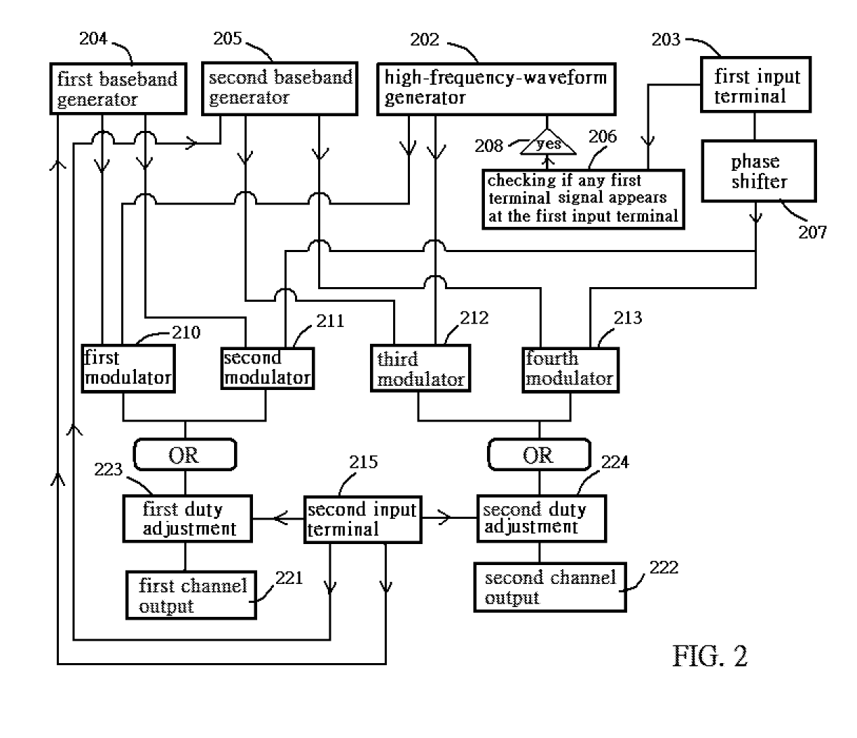

Before progressing further, two new PWM controllers employed in two new switching circuits will be introduced first. A first PWM controller with one output operated by a flow chart has been shown in FIG. 1 and a second PWM controller with two outputs operated by a flow chart has been shown in FIG. 2. The two PWM controllers are based on a similar concept but with different numbers of outputs.

The first PWM controller is operated by a flow chart shown in FIG. 1.

A baseband generator 104 is for generating baseband waveform. A high-frequency-waveform generator 102 is for generating high-frequency waveforms. A first input terminal 103 and a second input terminal 111 of the PWM controller are for receiving external signals. For the purpose of convenience, the external signals respectively received at the first input terminal 103 and the second input terminal 111 are respectively called as the “first terminal signal” and the “second terminal signal”. A first modulator 109 and a second modulator 110 are respectively for modulating two waveforms. A phase shifter 106 is for 180° phase-shifting the first terminal signal received at the first input terminal 103.

A checker 105 will check if a first terminal signal appears at the first input terminal 103.

If a first terminal signal appears at the first input terminal 103 then the high-frequency-waveform generator 102 stops generating high-frequency waveform and the first terminal signal received at the first input terminal 103 is 180°-phase-shifted through the phase shifter 106 and the 180°-phase-shifted first terminal signal and the baseband waveform generated by the baseband generator 104 modulate together through the second modulator 110. A yes 108 means the first terminal signal appears at the first input terminal 103 and the high-frequency-waveform generator 102 stops generating high-frequency waveform.

If no first terminal signal appears at the first input terminal 103 then the high-frequency waveform generated by the high-frequency generator 102 and the baseband waveform generated by the baseband generator 104 will modulate together through the first modulator 109.

The modulated waveforms after modulation step can be further duty-adjusted as output 113 if the second terminal signal received at the second input terminal tells a such need. If the duty-adjusted step is not needed the modulated waveforms after modulation step can be output.

The second terminal signal received at the second input terminal 111 can be used to further adjust the next baseband waveform generated by the baseband generator 104. The second terminal signal is not limited, for example, it can be a signal from sensors such as temperature sensor, voltage sensor, current sensor or chemical sensor, a signal from an emergency procedure or a signal from a manual control.

The first PWM controller is operated by steps shown in the flow chart of FIG. 1 for m≧1,

checking if a first terminal signal appears at the first input terminal 103;

if no first terminal signal appears at the first input terminal 103, modulating a m^{th} high-frequency waveform generated by the high-frequency-waveform generator 102 with a m^{th} baseband waveform generated by the baseband generator 104;

if a first terminal signal appears at the first input terminal 103, stopping the high-frequency-waveform generator 102 from generating high-frequency waveform, and 180°-phase-shifting the first terminal signal received at the first input terminal 103, and modulating the phase-shifted first terminal signal received at the first input terminal 103 after the 180°-phase-shifting step with a m^{th} baseband waveform generated by the baseband generator 104;

checking if any second terminal signal appears at the second input terminal 111;

if a second terminal signal appears at the second input terminal 111, adjusting a duty cycle of the modulated waveform after the modulation step as an output 113 and adjusting an m+1^{th} baseband waveform generated by the baseband generator 104 according to the second terminal signal received at the second input terminal 111; and

if no second terminal signal appears at the second input terminal 111, outputting the modulated waveform after the modulation step.

The second PWM controller is based on the same concept with the first PWM controller but with two outputs. The second PWM controller having two outputs is operated by a flow chart shown in FIG. 2.

A first baseband generator 204 and a second baseband generator 205 are respectively for generating a first baseband waveform and a second baseband waveform which may be different. A high-frequency-waveform generator 202 is for generating high-frequency waveform. A first input terminal 203 and a second input terminal 215 are for receiving external signals. For the purpose of convenience, the external signals respectively received at the first input terminal 203 and the second input terminal 215 are respectively called as “first terminal signal” and “second terminal signal”. A first modulator 210, a second modulator 211, a third modulator 212 and a fourth modulator 213 are respectively for modulating two waveforms. A phase shifter 207 is for 180° phase-shifting the first terminal signal received at the first input terminal 203. For the purpose of convenience, the baseband waveforms respectively generated by the first baseband generator 204 and the second baseband generator 205 are respectively called as “first baseband waveform” and “second channel waveform” and an m^{th} waveform respectively generated by the first baseband generator 204 and the second baseband generator 205 can be respectively called as “first baseband m^{th} waveform” and “second baseband m^{th} waveform.

A checker 206 will check if a first terminal signal appears at the first input terminal 203.

If the checker 206 checks no first terminal signal at the first input terminal 203 then the first baseband waveform and the second baseband waveform respectively generated by the first baseband generator 204 and the second baseband generator 205 will respectively modulate with the high-frequency waveform generated by the high-frequency-waveform generator 202 respectively through the first modulator 210 and the third modulator 212.

If a first terminal signal appears at the first input terminal 203 then the high-frequency-waveform generator 202 stops generating high-frequency waveform and the first terminal signal received at the first input terminal 203 will be 180°-phase-shifted and the phase-shifted first terminal signal received at the first input terminal 203 after the 180°-phase-shifting step will be modulated with the first baseband waveform and the second baseband waveform respectively generated by the first baseband generator 204 and the second baseband generator 205 respectively through the second modulator 211 and the fourth modulator 213.

A yes 208 means that the first terminal signal appears at the first input terminal 103 and the high-frequency-waveform generator 102 stops generating high-frequency waveform.

The modulated waveforms after modulation step can be respectively further duty-adjusted before outputting if the second terminal signal received at the second input terminal tells a such need. If the duty-adjusted is not needed the modulated waveforms after modulation step can be output.

The second terminal signal received at the second input terminal 215 can be used to further adjust the next first baseband waveform and the next second baseband waveform respectively generated by the first baseband generator 204 and the second baseband generator 205. The second terminal signal is not limited, for example, it can be a signal from sensors such as temperature sensor, voltage sensor, current sensor or chemical sensor, a signal from an emergency procedure or a signal from a manual control.

The second PWM controller is operated by steps shown in the flow chart of FIG. 2 for m≧1,

checking if any first terminal signal appears at a first input terminal 203;

if no first terminal signal appears at the first input terminal 203, modulating the high-frequency waveform generated by the high-frequency-waveform generator 202 with the first baseband m^{th} waveform generated by the first baseband generator 204 through the first modulator 210 and the second baseband m^{th} waveform generated by the second baseband generator 205 through the third modulator 212;

if any first terminal signal appears at the first input terminal 203, stopping the high-frequency-waveform generator 202 from generating high-frequency waveform, and 180°-phase-shifting the first terminal signal received at the first input terminal 203, and modulating the phase-shifted first terminal signal received at the first input terminal 203 after the 180°-phase-shifting step with the first baseband m^{th} waveform generated by the baseband generator 204 through the second modulator 211 and the second baseband m^{th} waveform generated by the second baseband generator 205 through the fourth modulator 213;

checking if any second terminal signal appears at the second input terminal 215;

if a second terminal signal appears at the second input terminal 215, adjusting a duty cycle of the modulated waveforms either out from the first modulator 210 or the second modulator 211 as a first output 221 and adjusting a duty cycle of the modulated waveforms either out from the third modulator 212 or the fourth modulator 213 as a second output 222 according to the second terminal signal received at the second input terminal 215, and adjusting a first baseband m+1^{th} waveform generated by the first baseband generator 204 and a second baseband m+1^{th} waveform generated by the second baseband generator 205 according to the second terminal signal received at the second input terminal 215; and

if no second terminal signal appears at the second input terminal 111, outputting the modulated waveforms either out from the first modulator 210 or the second modulator 211 as a third output 221 and adjusting a duty cycle of the modulated waveforms either out from the third modulator 212 or the fourth modulator 213 as a fourth output 222.

The first PWM controller and the second PWM controller can be respectively used to construct a first switching circuit and a second switching circuit. A first switching circuit by employing the first PWM controller shown in FIG. 1 and a damper, a coupler, a reaction circuit and an action/reaction isolation device will be discussed first.

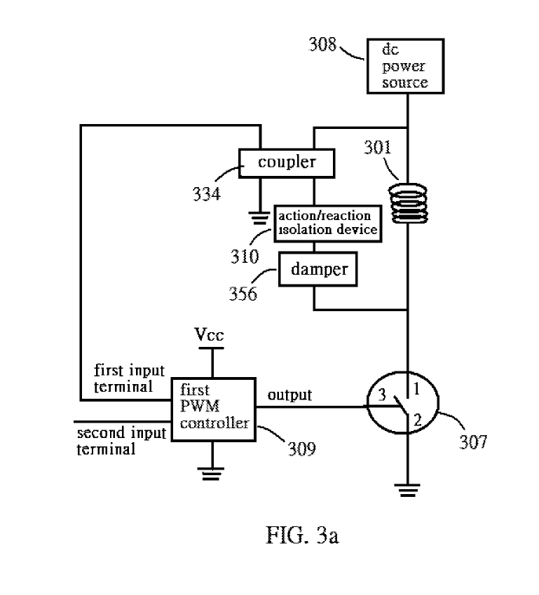

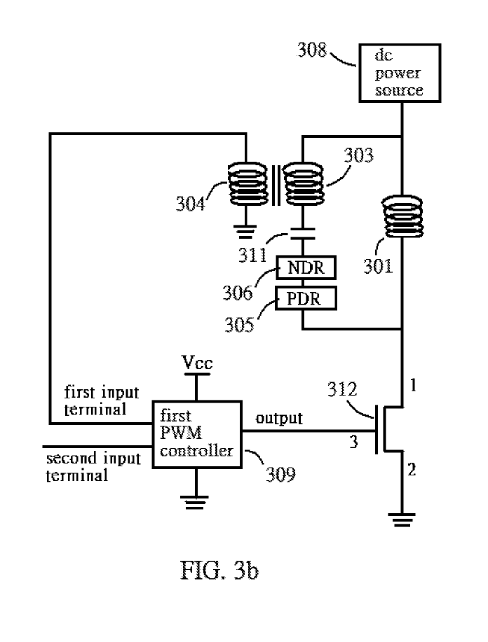

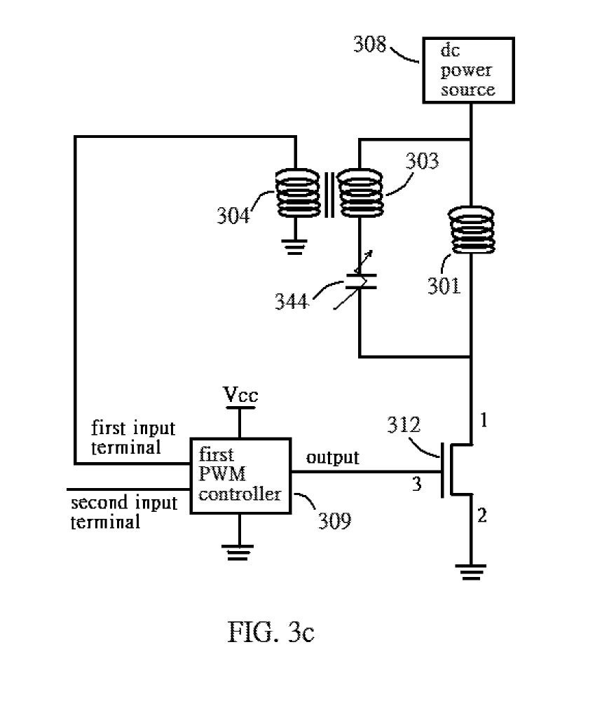

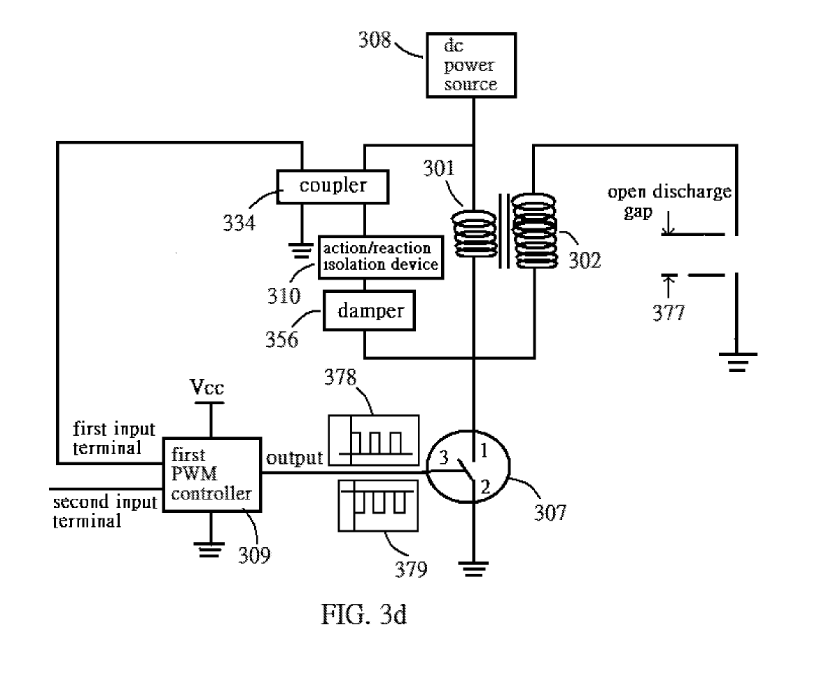

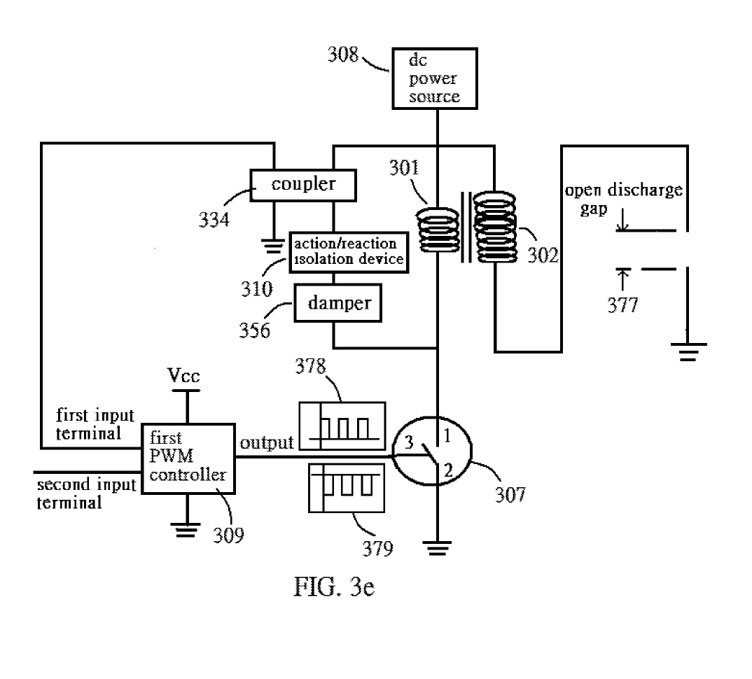

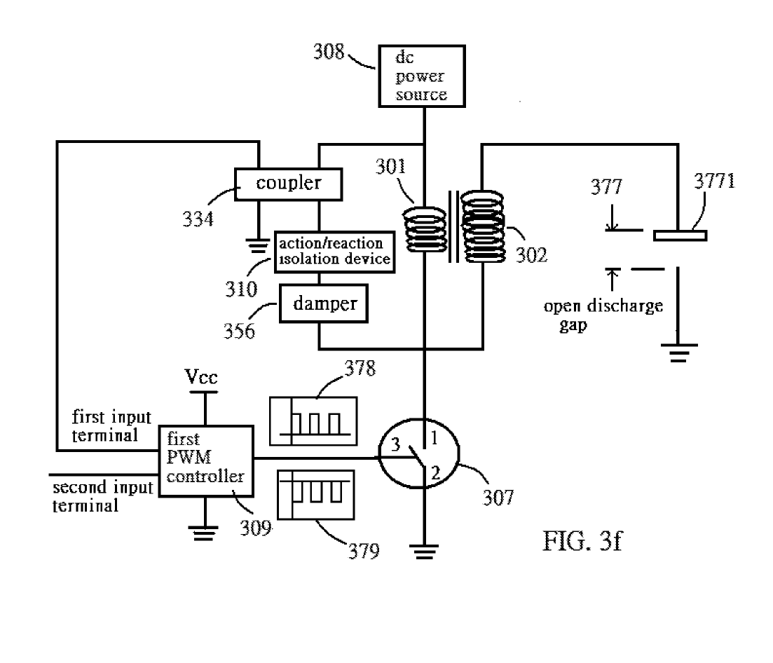

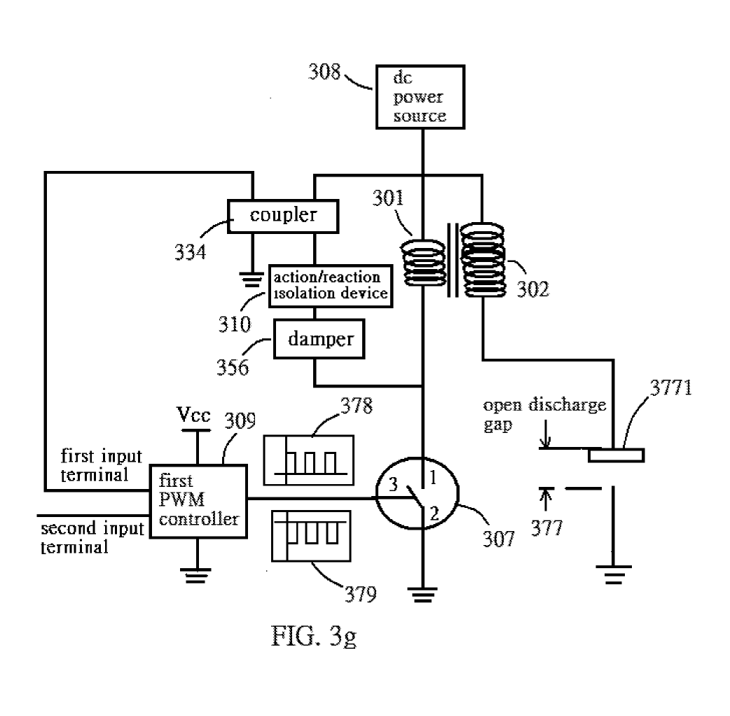

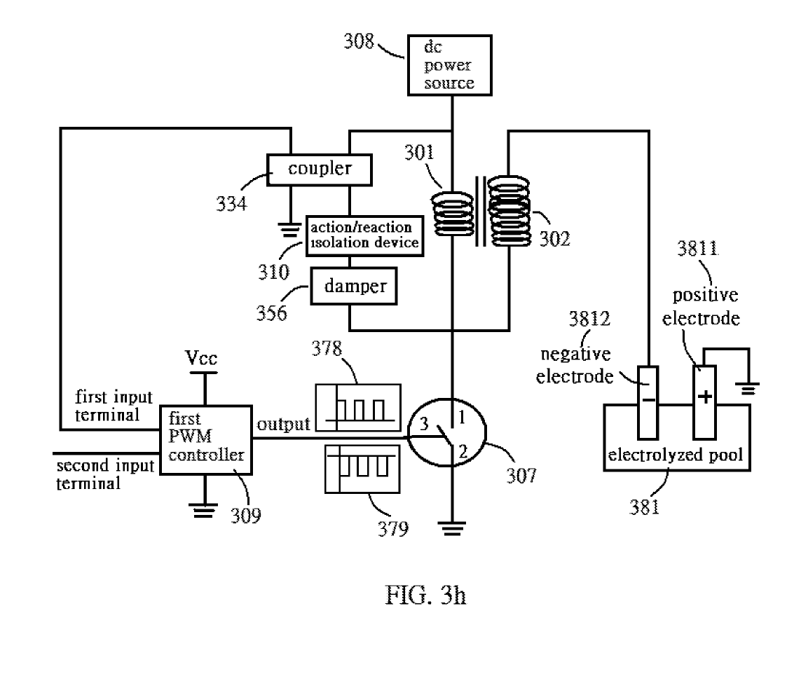

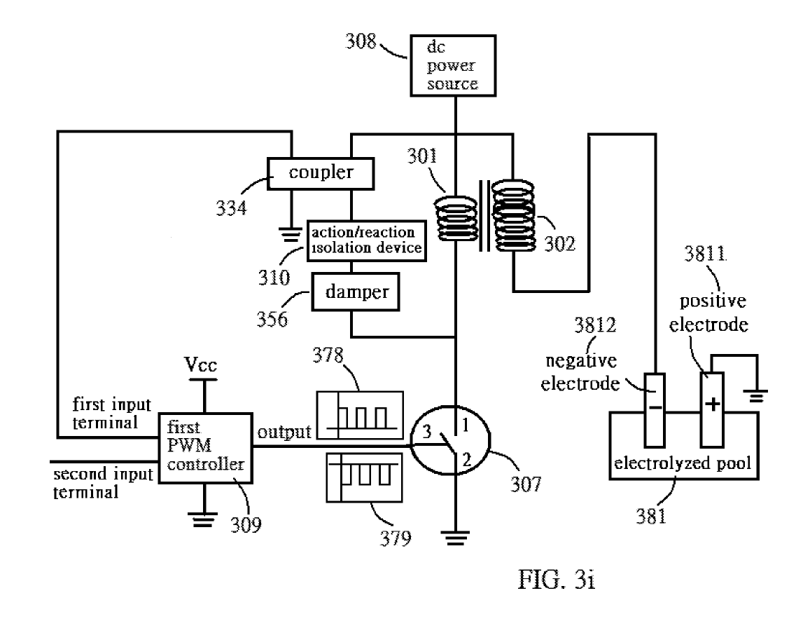

The first switching circuit shown in FIG. 3a comprises a dc power source 308, a first inductor 301 or called a first coil 301, a first switch 307, a first PWM controller 309 for controlling the open/close switchings of the first switch 307, and a “reaction circuit” in parallel with the first coil 301 comprising a damper 356, an action/reaction isolation device 310 and a coupler 334 electrically connected in series with each other.

The dc power source 308, the first coil 301 and the first switch 307 are electrically connected in series with each other by this sequence. The first input terminal, the second input terminal and the output of the first PWM controller 309 revealed in the embodiment of FIG. 1 are seen in the embodiment of FIG. 3a. The output of the first PWM controller 309 controls the close/open switchings (or on/off switchings) of the first switch 307.

Current from the dc power source 308 will flow through the first coil 301, the first switch 307 in close state and to the ground. When the first switch 307 is turned open the current is cut off and a high Lenz voltage is produced at the opened point of the first switch 307. The high frequency ac Lenz current produced by the Lenz voltage is opposite to the current from the dc power source 308 and hard to pass through the first coil 301 back to the dc power source 308 because the impedance of the first coil 301 becomes very big due to the high frequency Lenz current excitation so that a circuit, which is called “reaction circuit”, in parallel with the first coil 301 is prepared for the opposite Lenz current to pass. For the embodiment of FIG. 3a, the reaction circuit comprises a damper 356, an action/reaction isolation circuit 310 and a coupler 334 electrically connected in series with each other.

For any circuit, a power source applies power to a loading is an “action” and when the action stops “a reaction to the action” happens. For example, by employing the first switching circuit of FIG. 3a with a dc power source, when the first switch 307 is in close state a current from the dc power source 308 flowing through loadings, which include the first coil 301 and the first switch 307, is “an action” and when the first switch 307 is in open state the current from the dc power source 308 is cut off at the first switch 307, the action stops, and an ac Lenz current, which is a reaction to the action, produced by a Lenz voltage built at the opened point flows through the reaction circuit.

The action/reaction isolation device 310 is used to isolate an action, which is the current from the dc power source 308, from a reaction to the action, which is the Lenz current opposite to the current from the dc power source 308. For the case of the first switching circuit of FIG. 3a, ac and dc are separated.

The action/reaction isolation device 310 is not limited, for example, in the embodiment of FIG. 3a, the action/reaction isolation device can be an ac/dc isolation device such as a capacitor which can block the dc current from the dc power source 308 from flowing through the reaction circuit but allow the opposite ac Lenz current to pass the reaction circuit. Another embodiment, the action/reaction isolation device can be an unidirectional device such as a diode for only allowing current to flow in one way. The unidirectional diode such as a diode stops current from the dc power source 308 flowing through the reaction circuit but allows the opposite Lenz current to flow through the reaction circuit.

The coupler 334 is for coupling the waveform of the ac Lenz current flowing through the reaction circuit into the first PWM controller 309 through its first input terminal. The coupler 334 is not limited. The coupler 334 can be a capacitive, an inductive or a resistive coupler, for example, it can be a capacitor, a resistor or a transformer.

The damper 356 is for dissipating or stablizing the Lenz power in the reaction circuit and the damper is not limited. An embodiment, the damper 356 can be realized by a PDR device and a NDR device electrically connected in series as revealed in the background information section. Another example, the damper 356 can be our previous invention “an energy discharge capacitor” which also comprises a PDR device and a NDR device coupled in series.

The dc power source 308, damper 356, action/reaction isolation device 310 and coupler 334 are not limited in the present invention. The dc power source 308 can be a battery, a capacitor, a photo-electricity conversion device such as solarcell battery or a fuel cell. The action/reaction isolation device 310 can be an unidirectional device as a diode or an ac/dc isolation device as a capacitor. The coupler 334 can be a capacitive, an inductive or a resistive coupler, for example, it can be a capacitor, a resistor or a transformer. The damper 356 can be realized by a PDR device and a NDR device electrically connected in series or an energy discharge capacitor revealed in our previous invention.

The first switch 307 of FIG. 3a comprises a first, second and third terminals of which the electrical connection or disconnection of the first and second terminals respectively marked by 1 and 2 are controlled by the signal received on its third terminal marked by 3. The output of the first PWM controller 309 electrically connects the third terminals of the first switch 307 for controlling the electrical connection or disconnection of the first and second terminals of the first switch 307. The first switch 307 is not limited, for example, the first switch 307 can be a “power electronic device” such as a power transistor, which can duplicate the waveform received on its third terminal, or a SCR, which can not duplicate the waveform received on its third terminal. For the purpose of convenience, a switch which can duplicate the waveform received on its third terminal is called duplicatable switch in the present invention. A switch which can not duplicate the waveform received on its third terminal is called non-duplicatable switch in the present invention. The first switch 307 shown in FIG. 3a should be a duplicatable switch.

The waveform of the ac Lenz current going through the reaction circuit conceals the frequency responses of the loadings, which include the first switch 307 and the first coil 301, in the first switching circuit. The ac Lenz current is opposite to the current from the dc power source 308 means their phases differ 180° so that the ac Lenz current flowing through the reaction circuit should be 180°-phase-shifted before being modulated with the baseband waveform generated by the baseband generator of the first PWM controller 309. The 180°-phase-shifted waveform of the Lenz current is coupled into the first PWM controller 309 through its first input terminal to modulate with the baseband waveform generated by the baseband generator. According to the second input signal received at the second input terminals, the duty of the waveform after modulating step and the next baseband waveform generated by the baseband generator can be further adjusted. The second input signal can be from manual control, an emergency procedure or a sensor such as current sensor, voltage sensor, thermal sensor or chemical sensor, etc.

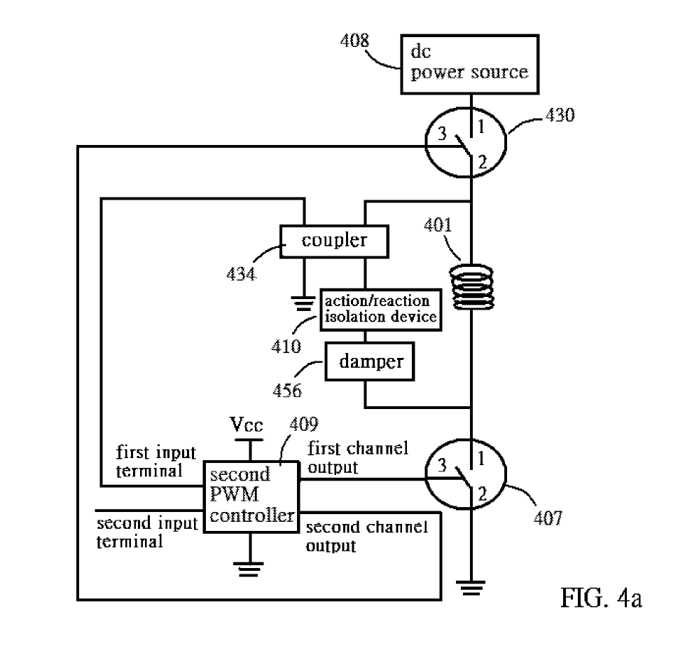

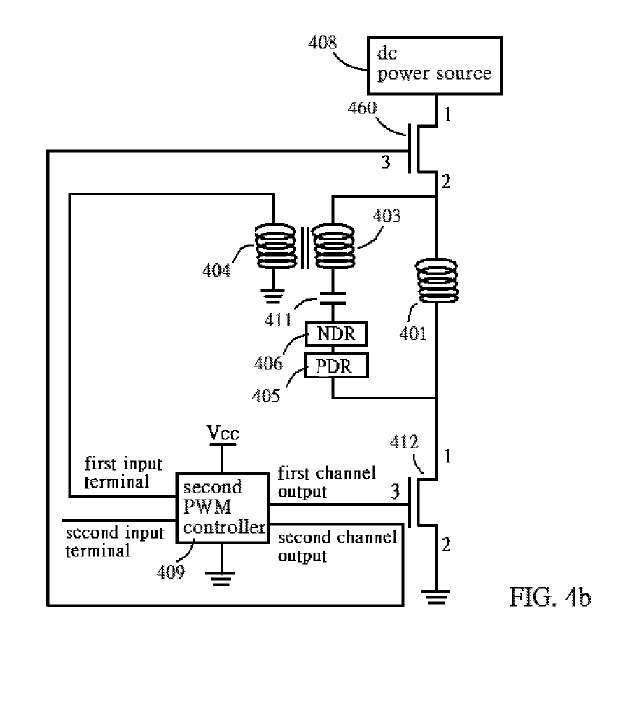

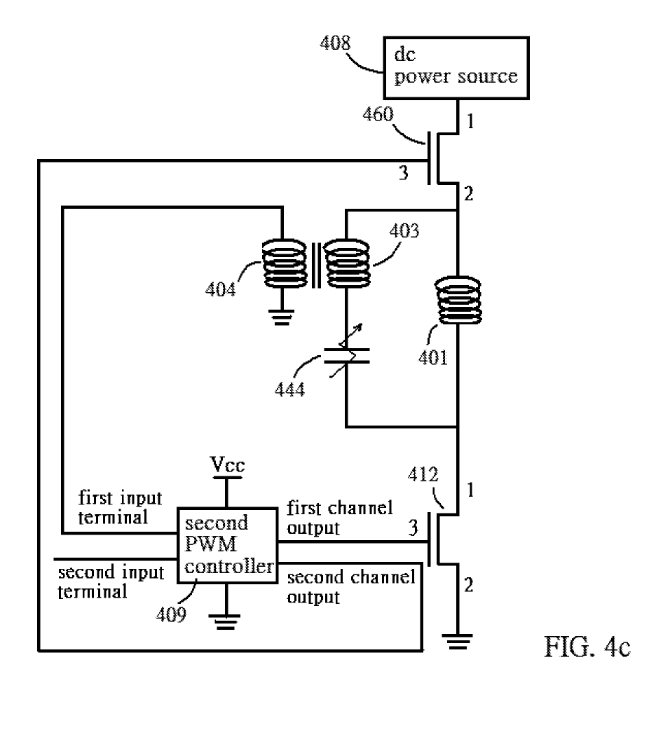

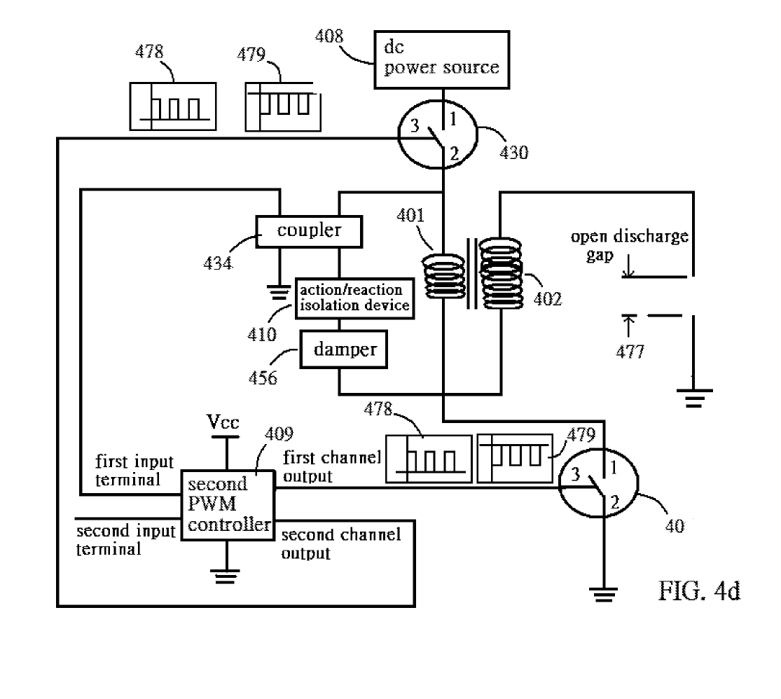

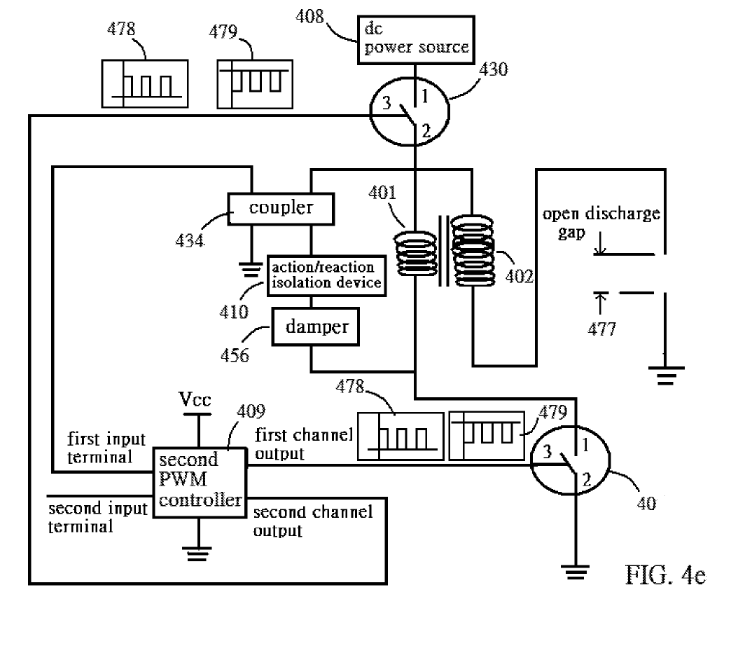

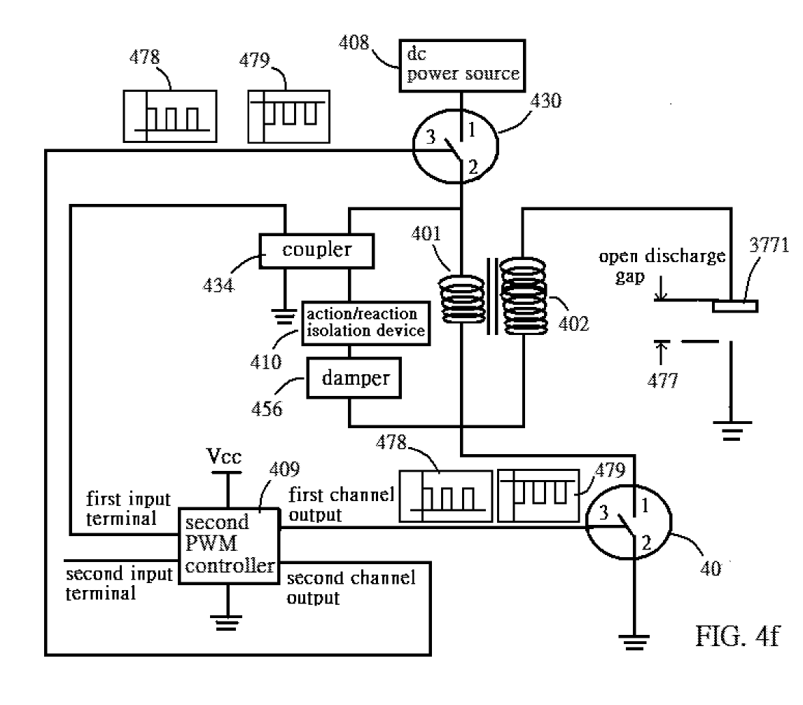

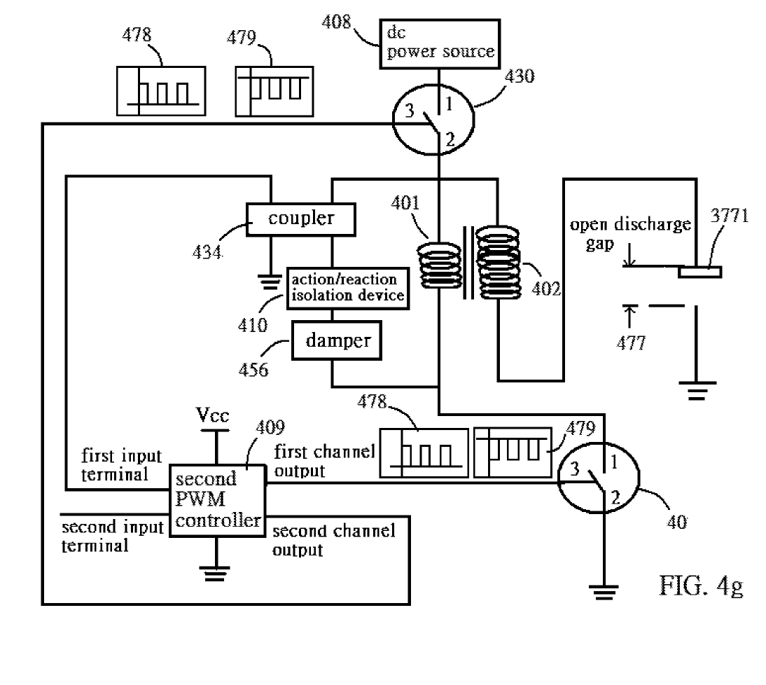

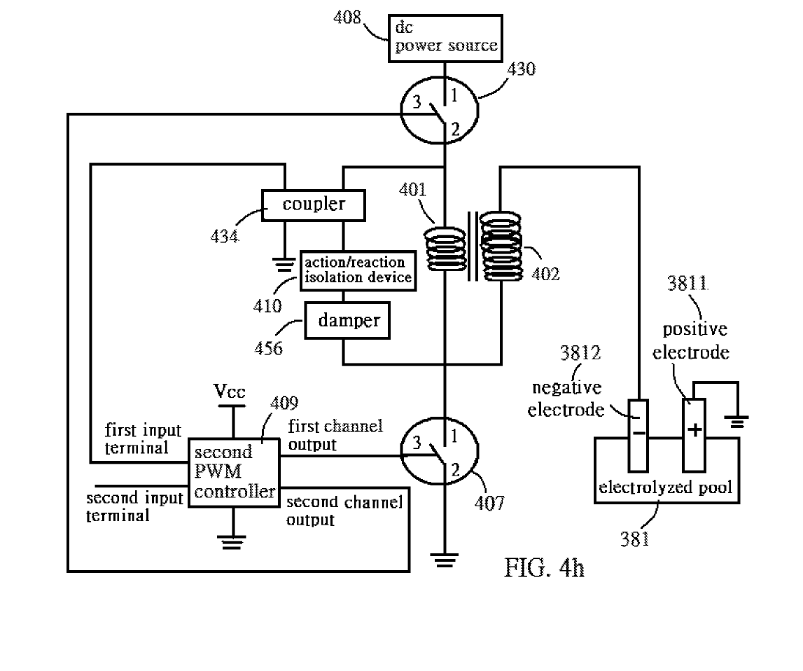

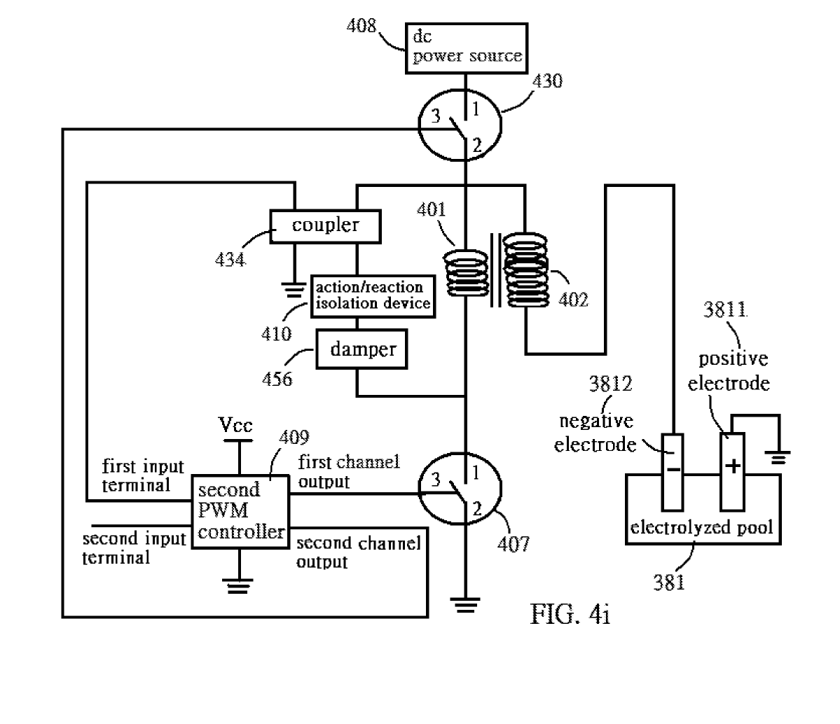

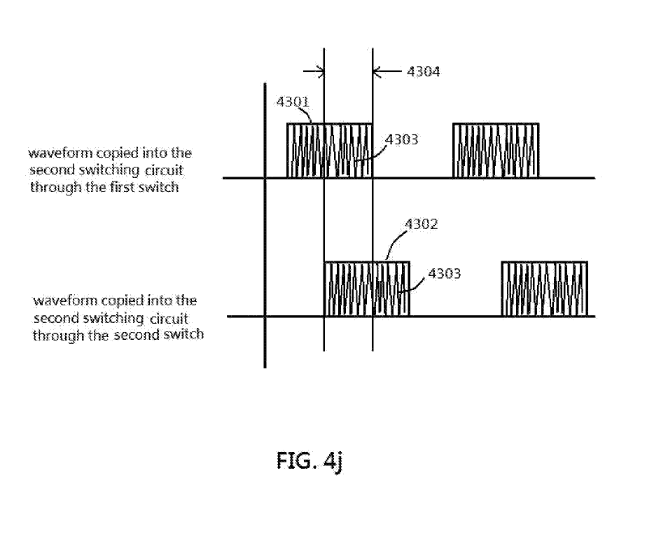

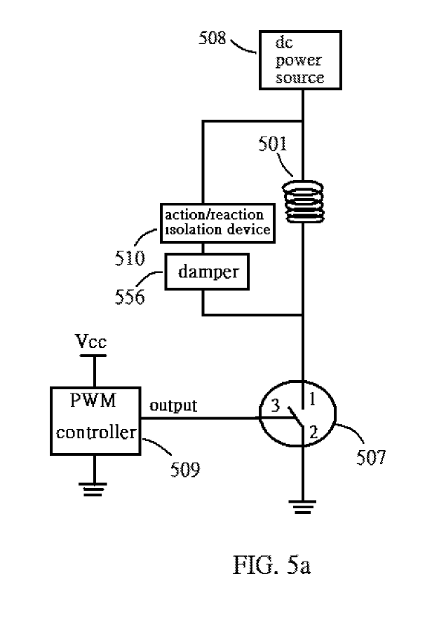

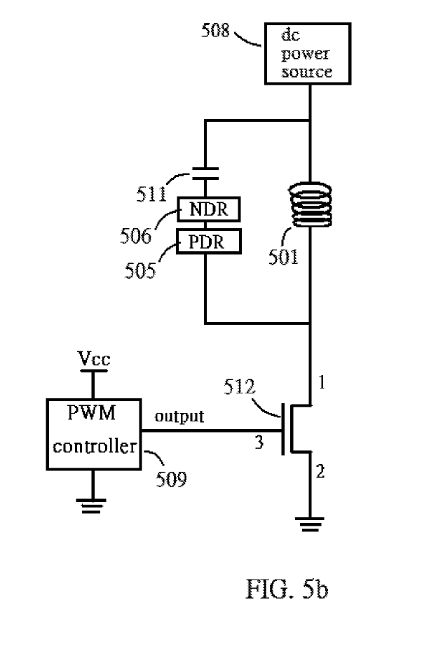

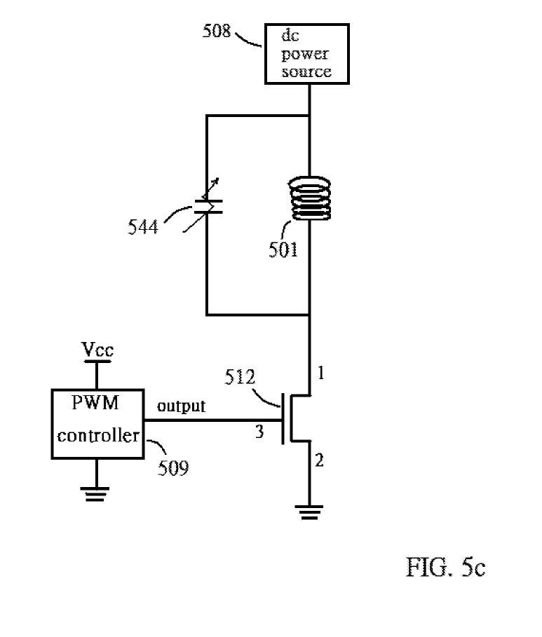

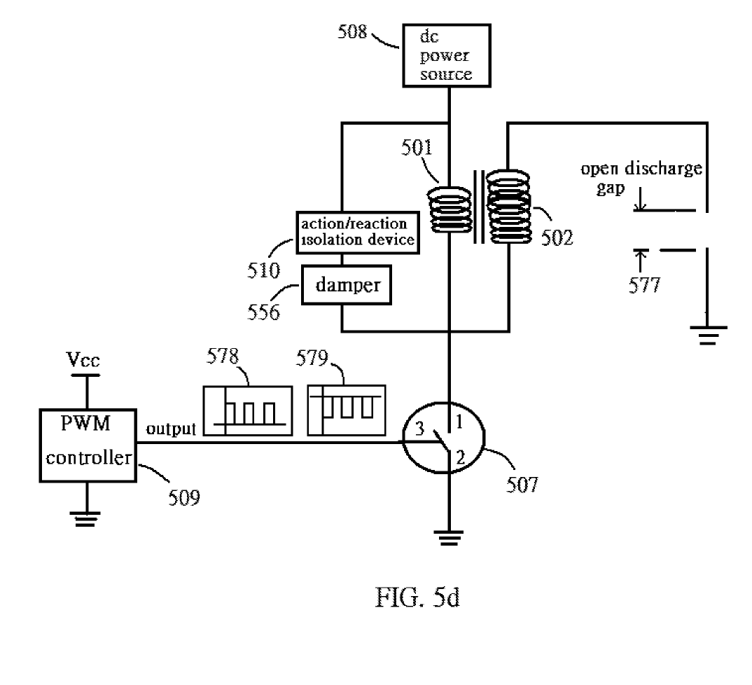

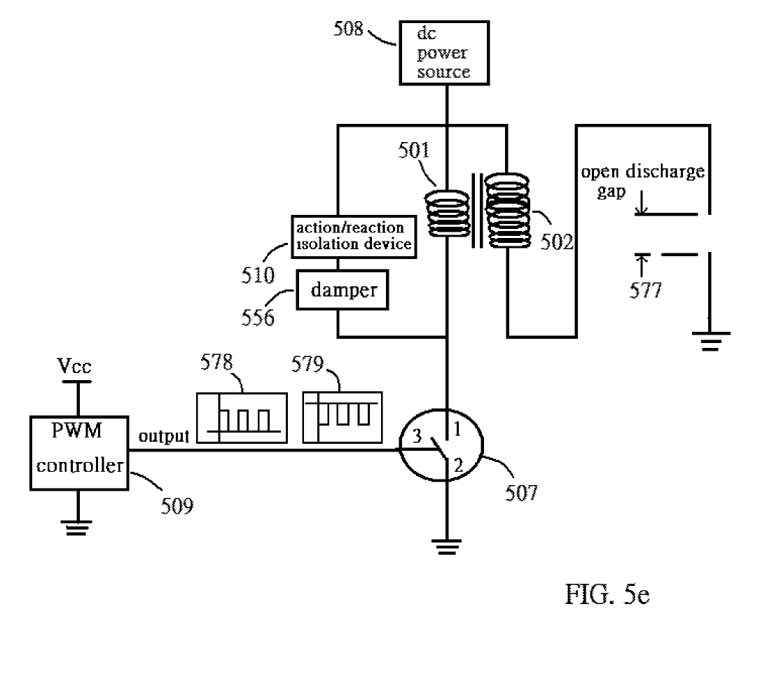

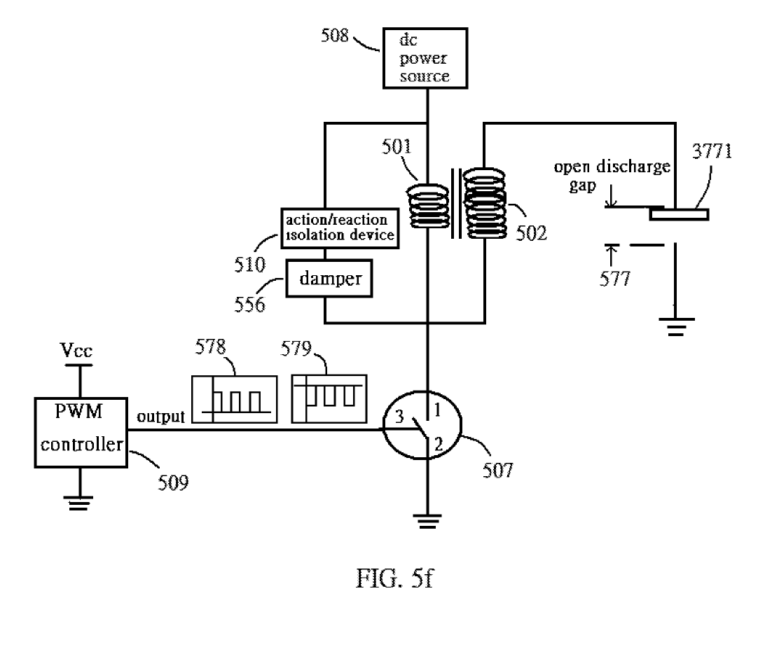

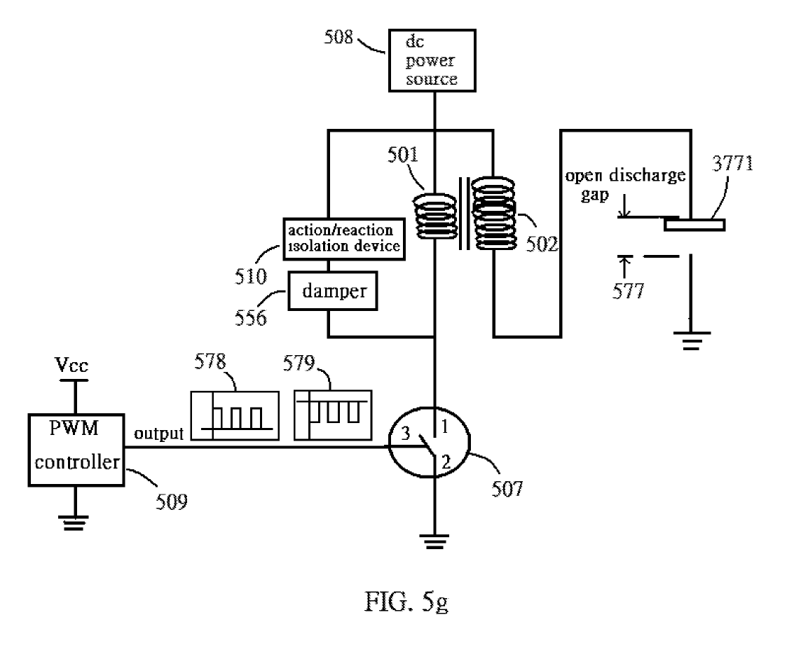

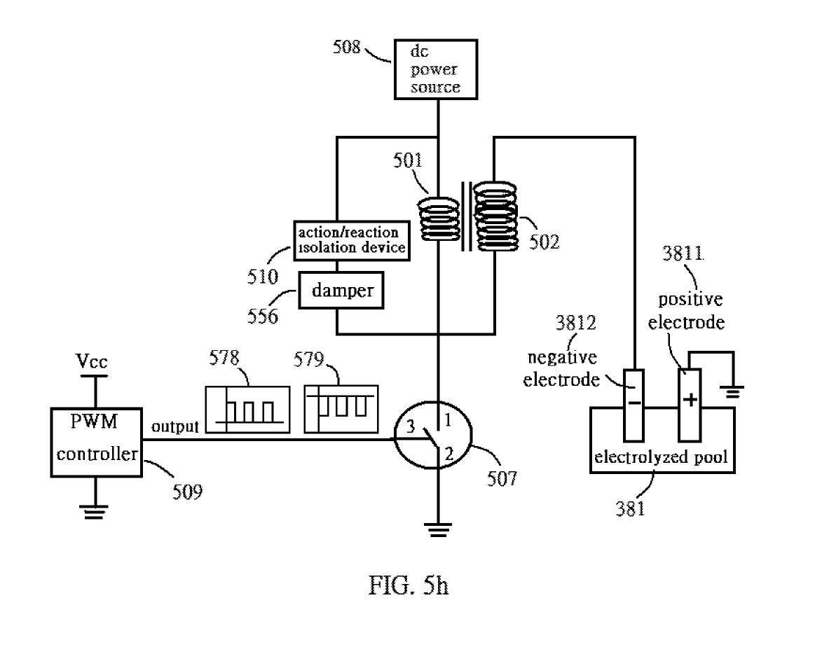

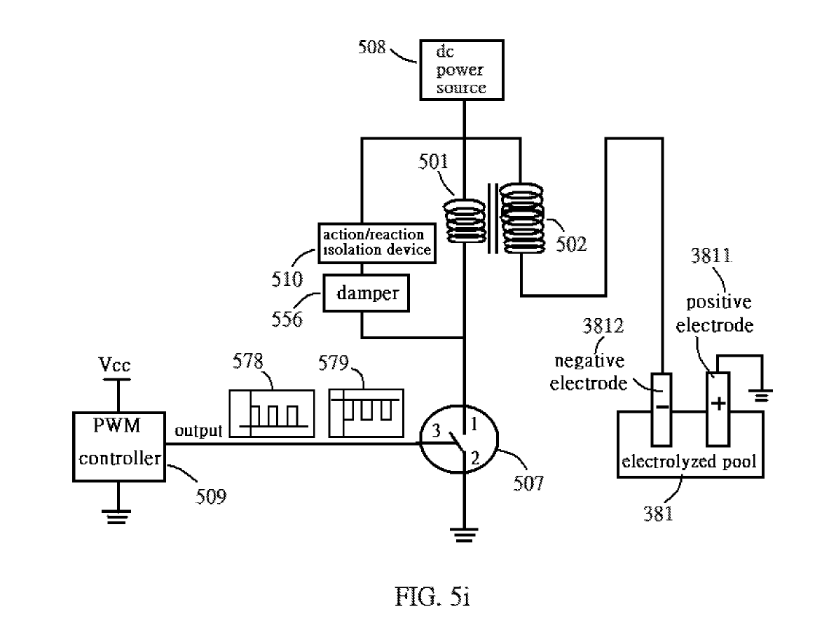

The waveform of the output of the first PWM controller will be copied into the first switching circuit through its first switch 307 and the waveform conceals the frequency responses of the loadings of the first switching circuit so that the on/off switchings of the first switch 307 can be more precisely controlled and the synchronization can be easier achieved. The waveform generated by the baseband generator of the first PWM controller is not limited. The waveform output from the first PWM controller is not limited, for example, the waveform can be a positive-duty-control waveform or a negative-duty-control waveform. A positive-duty-control waveform output 378 and a negative-duty-control waveform output 379 can be seen in FIGS. 3d and 3e, a positive-duty-control waveform output 478 and a negative-duty-control waveform output 479 can be seen in FIGS. 4d and 4e and a positive-duty-control waveform output 578 and a negative-duty-control waveform output 579 can be seen in FIGS. 5d and 5e.

The more detailed description about the first PWM controller can be referred back to the embodiment of the second PWM controller of FIG. 1. FIG. 3b has shown the result after the following substitutions of the switching circuit of FIG. 3a of which the first switch 307 is designated by a power transistor 312, the damper 356 is realized by a PDR device 305 and a NDR device 306 electrically connected in series, the action/reaction isolation device 310 is realized by a capacitor 311 and the coupler 334 is realized by a transformer which is formed by a third coil 303 and a fourth coil 304. The waveform of the ac Lenz current flowing through the third coil 303 will be induced on the fourth coil 304 and fed into the first PWM controller 309 through its first input terminal.

The capacitor 311, PDR device 305 and NDR device 306 can be replaced by an energy-discharge capacitor revealed by our previous invention. FIG. 3c has shown the embodiment of FIG. 3b with its capacitor 311, PDR device 305 and NDR device 306 substituted by an energy-discharge capacitor 344. The inventive energy-discharge capacitor has characterized its energy discharging and damping capability with very wide bandwidth as revealed by our previous invention.

The concept of the reaction circuit is not limited to the first switching circuit of FIG. 3 instead it can be extended to any circuit. In any circuit, the reaction circuit can be defined to only allows “reaction” ac Lenz current to flow through the reaction circuit and prohibits dc from flowing through the reaction circuit and the reaction circuit comprises an action/reaction isolation device for isolating ac Lenz current and dc and a damper for stabilizing the ac Lenz current flowing through the reaction circuit.

A second switching circuit employing the second PWM controller revealed in the embodiment of FIG. 2 has been shown in FIG. 4a. The second switching circuit shown in FIG. 4a comprises two switches and a coil disposed between the two switches electrically connected in series with each other and the switchings of the two switches are respectively controlled by the two outputs of the second PWM controller.

The second switching circuit of FIG. 4a comprises a dc power source 408, a second switch 430, a first coil 401 and a first switch 407 electrically connected in series with each other with the first coil 401 disposed between the first switch 407 and the second switch 430. The first and second channel outputs of the second PWM controller 409 respectively control the switchings of the first switch 407 and the second switch 430. As same as the first switching circuit of FIG. 3a, a “reaction circuit” is in parallel with the first coil 401 and it comprises a damper 456, an action/reaction isolation device 410 and a coupler 434 electrically connected in series with each other.

FIG. 4b has shown the result after the following substitutions of the switching circuit of FIG. 4a. The first switch 407 is designated by a first power transistor 412, the second switch 430 is designated by a second power transistor 460, the damper 456 is realized by a PDR device 405 and a NDR device 406 electrically connected in series, the action/reaction isolation device 410 is realized by a capacitor 411 and the coupler 434 is realized by a transformer which is formed by a third coil 403 and a fourth coil 404. FIG. 4c has shown the second switching circuit of FIG. 4b with its capacitor 411, PDR device 405 and NDR device 406 substitued by an energy discharge capacitor 444.

The waveform of the ac Lenz current going through the reaction circuit conceals the frequency responses of the loadings, which include the first switch 407, the second switch 430 and the first coil 401, in the second switching circuit. The ac Lenz current is opposite to the current from the dc power source 408 means their phases differ 180° so that the ac Lenz current should be 180°-phase-shifted before being modulated with the baseband waveforms generated by the baseband generators of the second PWM controller. The 180°-phase-shifted waveform of the Lenz current is coupled into the second PWM controller 409 through its first input terminal to respectively modulate with the waveform of the first baseband generator and the waveform of the second baseband generator. According to the second input signal received at the second input terminals, the duty of the waveforms after modulation step and the next baseband waveforms respectively generated by the first baseband generator and the second baseband generator can be further adjusted. The second input signal can be from manual control, an emergency procedure or a sensor such as current sensor, voltage sensor, thermal sensor or chemical sensor.

The waveforms of the two outputs of the second PWM controller will be copied into the second switching circuit through the first and second switches 407, 430 and the waveforms conceal the frequency responses of the loadings so that the on/off switchings of the two switches 407, 430 can be more precisely controlled and the synchronization can be easier obtained. The waveforms generated by the first baseband generator and the second baseband generator of the second PWM controller are not limited. The waveforms output from the second PWM controller are not limited, for example, they can be a positive-duty-control waveform or a negative-duty-control waveform.

The more detailed description about the second PWM controller can be referred back to the embodiment of the second PWM controller of FIG. 2.

Shown in the second switching circuit of FIG. 4a, the current from the dc power source 408 acting on the first coil 401 only happens when both switches 407, 430 are in close state which can be viewed as an overlapping of two waveforms respectively output from the second PWM controller respectively on the first and second switches 407, 430.

FIG. 4j can be used to explain this in more detailed way. FIG. 4j has shown a first baseband waveform 4301 modulated with a 180°-phase-shifted waveform of Lenz current 4303 on the first switch 407 and a second baseband waveform 4302 modulated with a 180°-phase-shifted waveform of Lenz current 4303 on the second switch 430 and an overlapping 4304 between the two waveforms. The overlapping 4304 expresses the chance that both the two switches 407, 430 are on at a same time. The bigger overlapping means the more numbers of both the two switches are on resulting in bigger power pulled out from the dc power source 408 and the smaller overlapping means the fewer numbers of both the two switches are on resulting in less power pulled out from the dc power source 408. The frequency responses of the second switching circuit is the multiplication of the frequency response of each switch so that the frequency response of the second switching circuit can be very high. According to the embodiment of the second PWM controller of FIG. 2, the waveforms (including phase) of the two outputs of the second PWM controller can be adjusted resulting in the adjustment of the overlapping area.

The second switching circuit has featured ultra-high frequency response and it has also featured that the overlapping 4304 can be slowly adjusted from nothing or a very small area to an expective larger area, which provides better security for large power source condition. In other words, for high power and high frequency applications the second switching circuit is the right choice.

The second switching circuits of FIGS. 4a, 4b and 4c should contain at least a duplicatable switch. Because the outputs from the second PWM controller contains the frequency responses of the two switches 407, 430 so that it will be safer for both two switches 407, 430 are duplicatable switches.

A third switching circuit by employing a conventional PWM controller has been respectively shown in FIGS. 5a, 5b and 5c. The third switching circuit in general form has been shown in FIG. 5a of which a conventional PWM controller 509 has no first input terminal as the first and second PWM controllers and the reaction circuit in parallel with the first coil 501 doesn't need the coupler. The reaction circuit in parallel with the first coil 501 comprises a damper 556 and an action/reaction isolation device 510 electrically connected in series with each other.

The third switching circuits respectively shown in FIGS. 5a, 5b and 5c are more suitable for low frequency and low power applications, and the second switching circuit is good for extra high frequency and high power applications, and the first switching circuit sits between them. The dc power source, damper, action/reaction isolation device, switch and coupler of the first, second and third switching circuits are not limited in the present invention. The dc power source can be a capacitor, battery, solar cell device or fuel cell. The action/reaction isolation device can be an unidirectional device as a diode or an ac/dc isolation device as a capacitor. The coupler can be a capacitive, an inductive or a resistive coupler, for example, it can be a capacitor, a resistor or a transformer. The damper can be realized by a PDR device and a NDR device electrically connected in series or an energy discharge capacitor revealed in our previous invention. The switch can be a duplicatable switch such as a “power electronic device” such as a power transistor or a non-duplicatable switch such as a SCR.

The first, second and third switching circuits can be respectively employed to respectively construct a first, second and third high voltage discharge circuits. An open discharge gap means an open circuit. The open discharge gap can be viewed to have two terminals with an opening between the two terminals. A second coil is needed to form a transformer with the first coil respectively of the first, second and third switching circuits for boosting voltage and a terminal of the second coil electrically connects the low side terminal or the high side terminal of the first coil respectively of the first, second and third switching circuits and the other terminal of the second coil electrically connects a first terminal of the open discharge gap and a second terminal of the open discharge gap electrically connected to a low side such as the ground.

For example by using the first switching circuit of FIG. 3a, a first high voltage discharge circuit can be obtained by electrically connecting a terminal of a second coil 302 with the low side terminal or the high side terminal of the first coil 301 and letting the other terminal of the second coil 302 electrically connect a first terminal of an open discharge gap 377 and a second terminal of the open discharge gap 377 electrically connected to the ground to complete a loop. The second coil 302 forms a trans-former with the first coil 301 for boosting voltage. For the purpose of convenience, the terminal of the second coil electrically connecting the open discharge gap is called “driving terminal of the second coil” in the present invention.

FIG. 3d has shown a first high voltage discharge circuit with a first terminal of a second coil 302 electrically connecting with the low side terminal of the first coil 301 and a second terminal of the second coil 302 electrically connects with the open discharge gap 377. FIG. 3e has shown a first high voltage discharge circuit with a first terminal of a second coil 302 electrically connecting with the high side terminal of the first coil 301 and a second terminal of the second coil 302 electrically connects with the open discharge gap 377. The polarities presented at the driving terminal of the second coil 302 respectively of the high voltage discharge circuits of FIG. 3d and FIG. 3e are opposite.

The same design also applies for the second and third high voltage discharge circuits. FIG. 4d has shown a second high voltage discharge circuit with a first terminal of a second coil 402 electrically connecting with the low side terminal of the first coil 401 and a second terminal of the second coil 402 electrically connects with the open discharge gap 477. FIG. 4e has shown a second high voltage discharge circuit with a first terminal of a second coil 402 electrically connecting with the high side terminal of the first coil 401 and a second terminal of the second coil 402 electrically connects with the open discharge gap 477.

FIG. 5d has shown a third high voltage discharge circuit with a first terminal of a second coil 502 electrically connecting with the low side terminal of the first coil 501 and a second terminal of the second coil 502 electrically connects with the open discharge gap 577. FIG. 5e has shown a second high voltage discharge circuit with a first terminal of a second coil 502 electrically connecting with the high side terminal of the first coil 501 and a second terminal of the second coil 502 electrically connects with the open discharge gap 577.

The polarities presented at the driving terminal of the second coil of the high voltage discharge circuits of FIG. 4d and FIG. 4e are opposite. The polarities presented at the driving terminal of the second coil of the high voltage discharge circuits of FIG. 5d and FIG. 5e are opposite. An uniq polarity, either positive polarity or negative polarity, is always kept at the driving terminal of the second coil of the first coil of the first, second and third high voltage discharge circuits.

The polarity presented at the driving terminal of the second coil of a high voltage discharge circuit is decided by the waveform output from the PWM controller and the low side or high side of the first coil of the switching circuits electrically connecting to the second coil. For example, the waveform output from the PWM controller can be a positive-duty-control waveform or a negative-duty-control waveform. FIGS. 3d and 3e have also shown a positive-duty-control waveform output 378 and a negative-duty-control waveform output 379, FIGS. 4d and 4e have shown a positive-duty-control waveform output 478 and a negative-duty-control waveform output 479 and FIGS. 5d and 5e have shown a positive-duty-control waveform output 578 and a negative-duty-control waveform output 579.

The high voltage discharge circuit has an open discharge gap so that it doesn't consume much significant current as short circuit does resulting in consuming less power. Any matter has bandgap, the high voltage discharge circuit uses high voltage to overcome the bandgap to cause some changes. For example, the high voltage discharge circuit can be an ionization driver by disposing an ion-release device by the open discharge gap under the influence of the high voltage built at the open discharge gap to release ions which can be a positive ions or a negative ions depending on the circuit used, a waste powdering driver by disposing a waste by the open discharge gap under the influence of the high voltage built at the open discharge gap to powder the waste, an electrolyzer driver by electrically connecting the two terminals of the open discharge gap of the high voltage discharge circuit respectively with the positive electrode and the negative electrode of an H₂O-containing electrolyzer to electrolyze H₂O and an arc welding driver by disposing a welding device by the open discharge gap under the influence of the high voltage built at the open discharge gap for a welding work.

A small rectangle 3771 disposed at one side of the open discharge gap is seen in FIGS. 3f, 3g, 4f, 4g, 5f and 5g. If the small rectangle 3771 is an ion-release device then the high voltage discharge circuits are used as ionization drivers. If the small rectangle 3771 is an welding matter then the high voltage discharge circuits are used as arc welding drivers. If the small rectangle 3771 is a waste then the high voltage discharge circuits are used as waste powdering drivers. The high volatge discharge circuit can also be used as electrolyzer driver. FIGS. 3h, 3i, 4h, 4i, 5h and 5i have shown the two terminals of the open discharge gap of each high voltage discharge circuit respectively electrically connect with the positive electrode 3811 and the negative electrode 3812 of an H₂O-containing electrolyzer 381 for separating the H₂ and O₂ gases respectively at its negative electrode and positive electrode.

The ion-release device is not limited, for example, it can be a carbon nanotube (CNT). The CNT can absorb H₂O in air and the positive polarity presented at the driving terminal of the second coil of an ionization driver excites the carbon nanotube to release positive ions H⁺ and the negative polarity presented at the driving terminal of the second coil of an ionization driver excites the carbon nanotube to release negative ions OH⁻.

For another example, the ion-release device can be fullerene-containing polymers or fullerene derivatives as in the form of Cₘ(OH)ₙ or hydrogenated fullerenes CₘH₇ₙ, where the m and n are not limited, for example, the m and n are integers and the m and n≧1. With m=60, C₆₀(OH)ₙ are very famous fullerene-containing polymers. Here following a brief introduction to fullerene is found in wikipedia “A fullerene is any molecule composed entirely of carbon, in the form of a hollow sphere, ellipsoid, or tube. Spherical fullerens are also called buckyballs, and cylindrical ones are called carbon nanotubes or buckytubes. Fullerenes are similar in structure to graphite, which is composed of stacked graphene sheets of linked hexagonal rings; but they may also contain pentagonal (or sometimes heptagonal) rings.” One of very famous fullerenes is C₆₀ discovered in 1985. Some fullerene-containing polymers or fullerene derivatives as in the form of Cₘ(OH)ₙ or hydrogenated fullerenes CₘHₙ have been successfully fabricated.

The water-soluble polyhydroxyfullerols C₆₀(OH)ₙ are very good in conductivity and the polyhydroxyfullerols C₆₀(OH)ₙ have characterized that a cloud of OH⁻ will be escaped from C₆₀ when the polyhydroxyfullerols C₆₀(OH)ₙ are applied by an electrical field. The polyhydroxyfullerols C₆₀(OH)ₙ can be good ion-release devices.

According to the switching circuits discussed above, ac-nature Lenz current is the reaction to the action and the ac-nature Lenz current flowing through the reaction circuit is isolated from dc of power source and the ac Lenz current can be stabilized by a damper in reaction circuit.

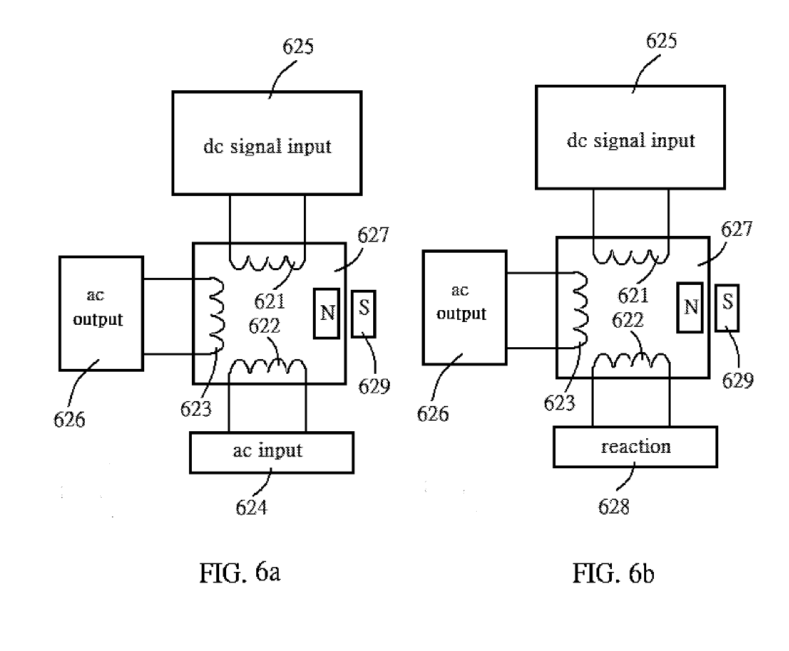

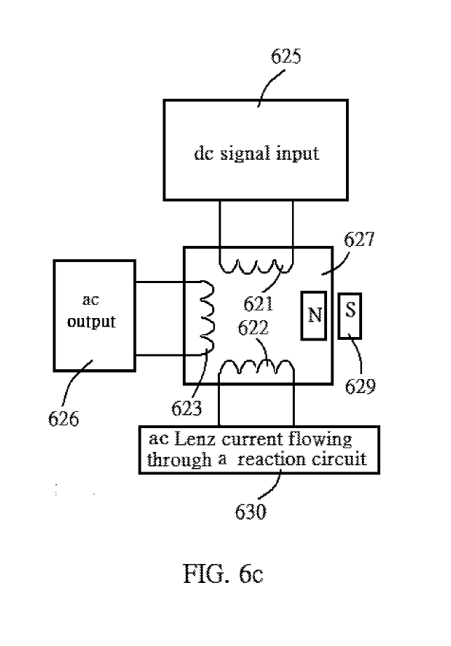

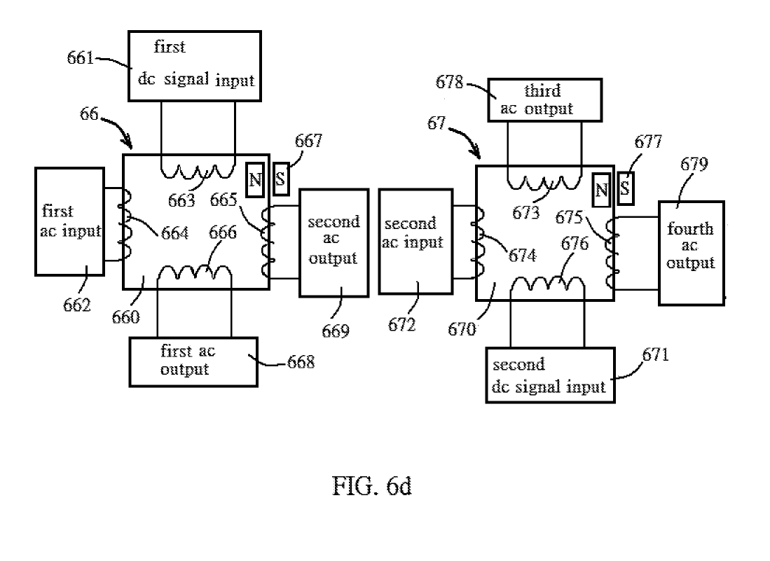

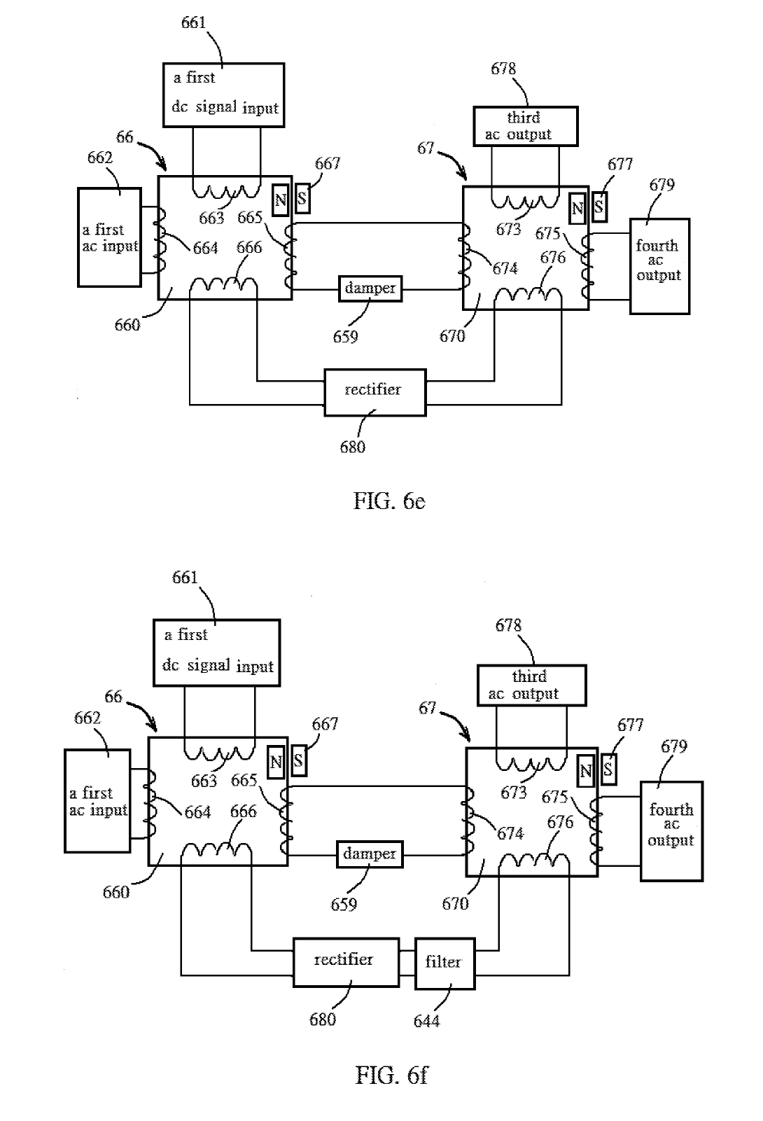

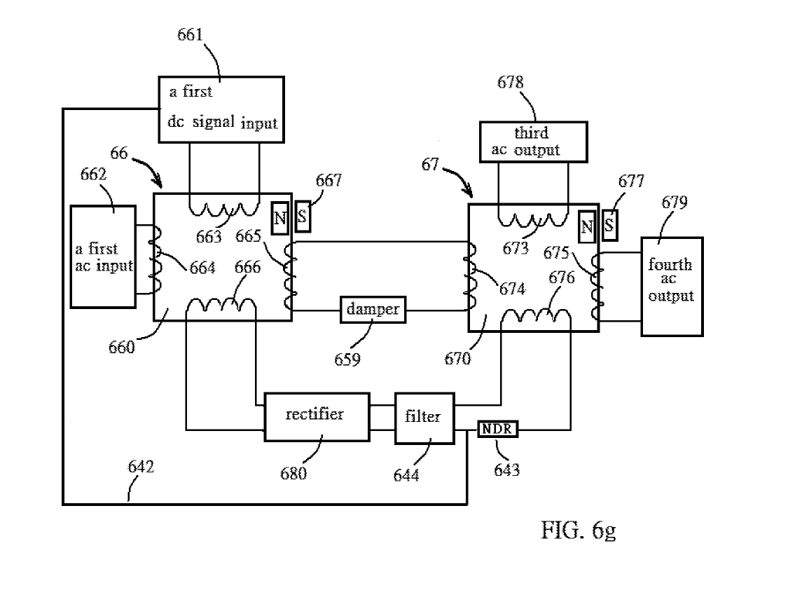

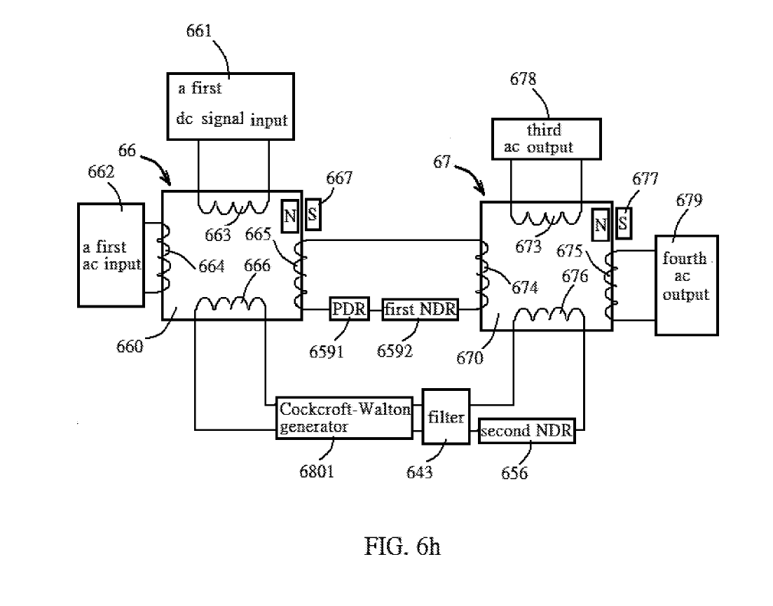

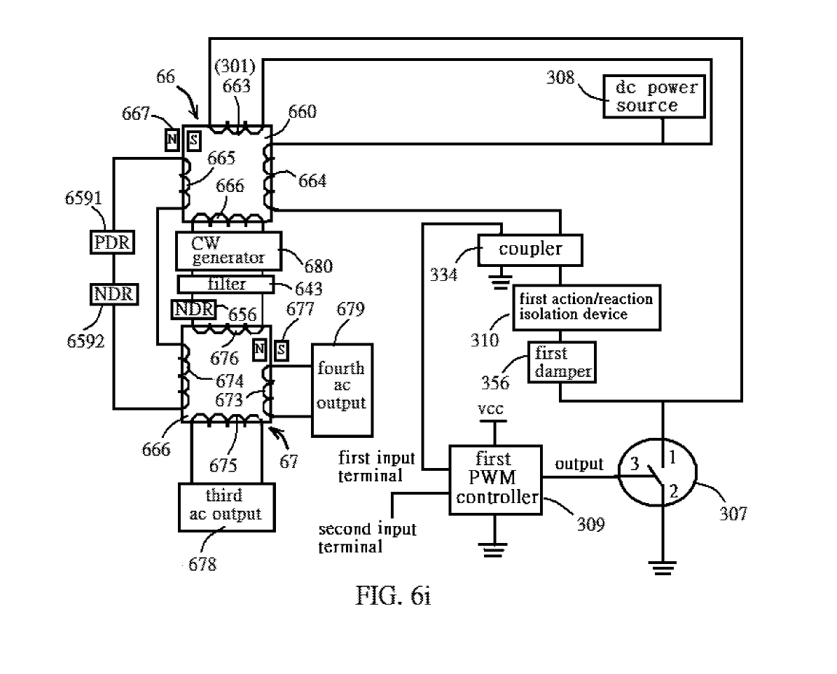

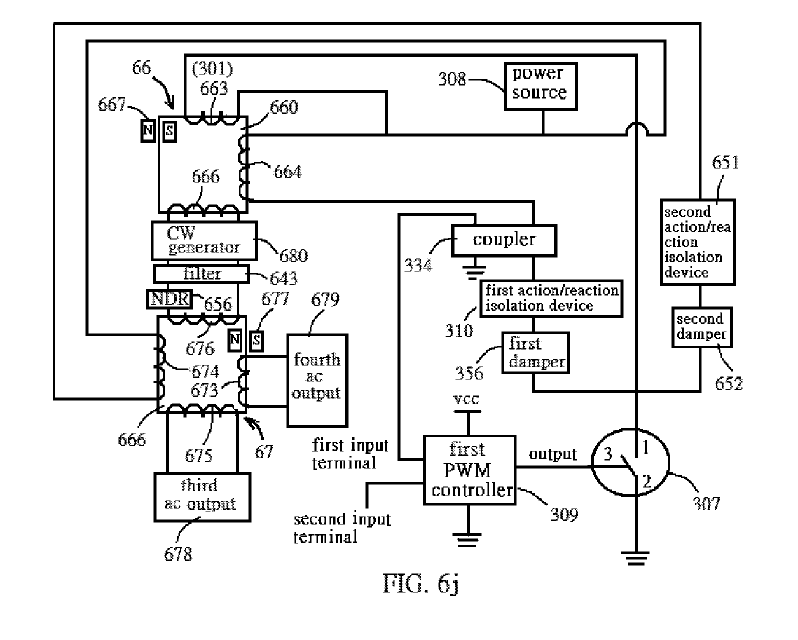

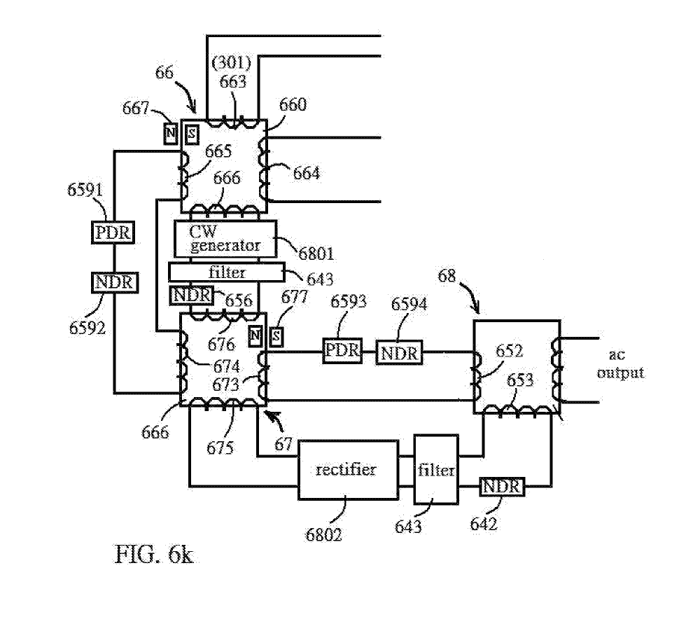

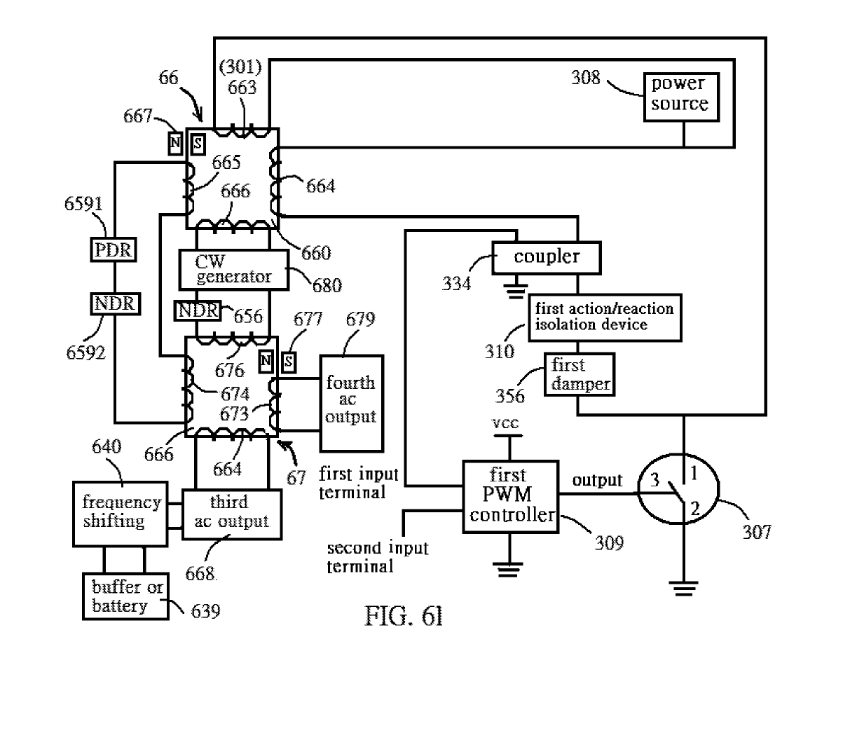

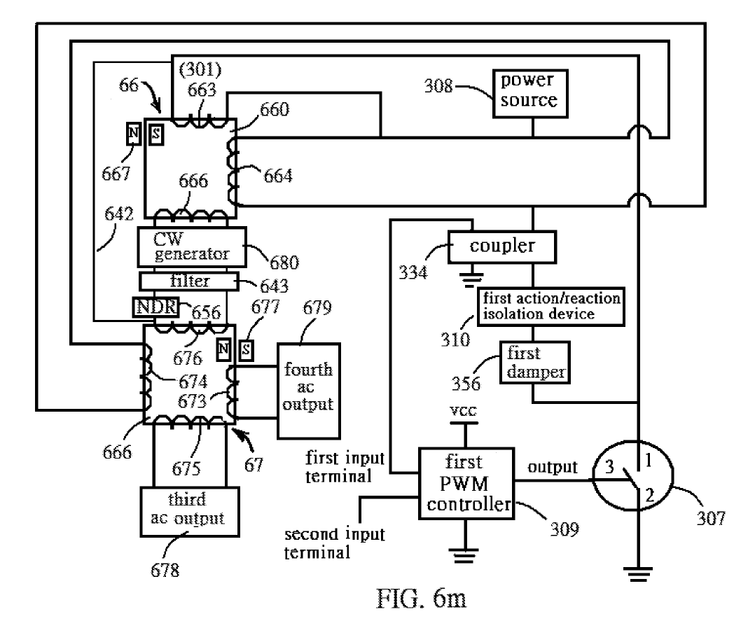

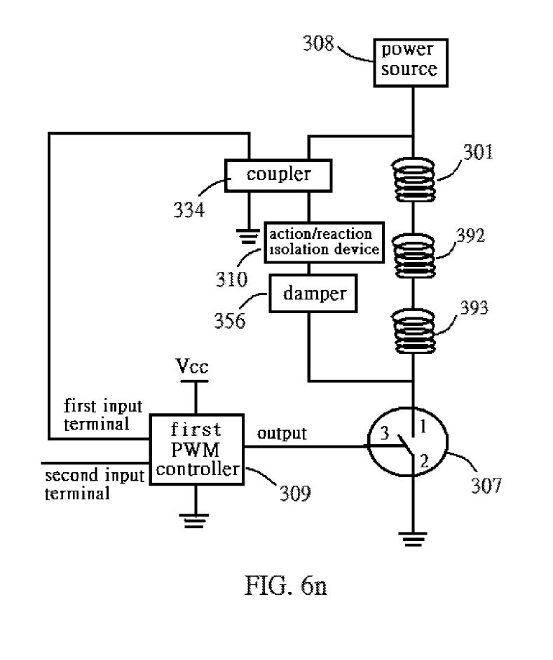

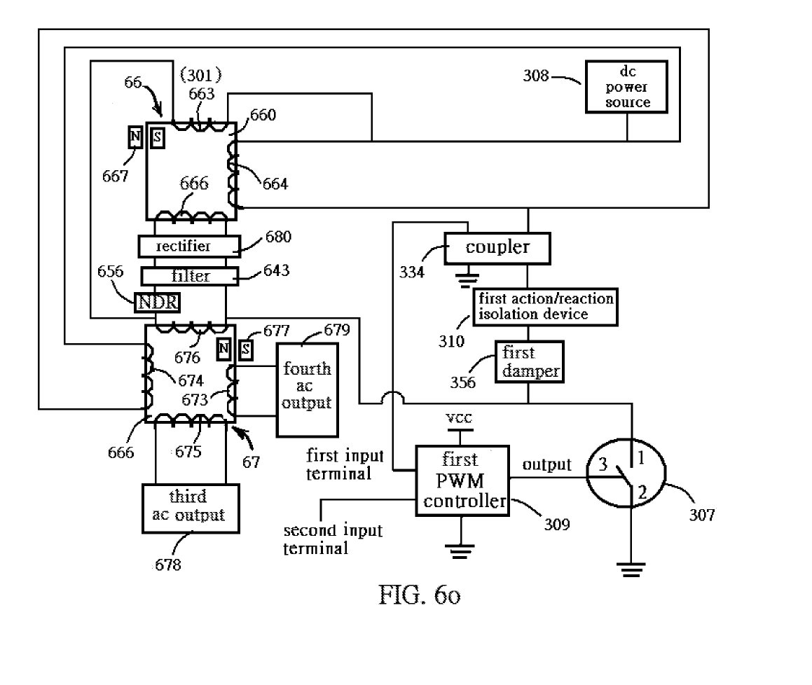

Magnetic amplifier has been invented for decades but its applications are limited because its amplication is limited and it requires an ac input. FIG. 6a has introduced the basic principle of a known magnetic amplifier.

A known magnetic amplifier shown in FIG. 6a comprises a first input coil 622, a second input coil 621 and a first output coil 623 respectively coiling around a magnetic core 627. The first input coil 622 and the second input coil 621 respectively receive an ac input 624 and a dc signal input 625 and the first output coil 623 outputs an ac output 626. An amplified power can be seen at the ac output 626. The dc signal input 625 means frequency-modulated dc.

FIG. 6a has also shown a static magnet 629, which provides static magnetic field, neighbors the magnetic core 627 as a dc bias to enhance the saturability of the magnetic core 627. Please note that the static magnet 629 has polarity orientation to the magnetic core 627 to gain better efficiency. The magnetic core 627 is not limited but a B-H satuable magnetic core is critical. The shape of the magnetic core is not limited.

The present invention has featured that the “reaction” ac Lenz current flowing through a reaction circuit of a circuit is used as the ac input to the magnetic amplifier, and the reaction circuit of the circuit comprises an action/reaction isolation device for isolating the ac Lenz current from the dc from power source and a damper for stabilizing the ac Lenz current flowing through the reaction circuit.

Based on FIG. 6a, FIG. 6b has shown the ac input 624 of FIG. 6a is marked by “reaction” 628 and FIG. 6c has shown the reaction 628 of FIG. 6b is further marked by “ac Lenz current flowing through a reaction circuit” 630.

A plurality of magnetic amplifiers can be coupled in series and the total gain of the magnetic amplifiers coupled in series is the multiplication of each gain of each magnetic amplifier. Two magnetic amplifiers coupled in series will be discussed first.

FIG. 6d has shown a first magnetic amplifier 66 having a first input coil 664, a second input coil 663, a first output coil 666 and a second output coil 665 coiling around a first magnetic core 660 and a second magnetic amplifier 67 having a third input coil 676, a fourth input coil 674, a third output coil 673 and a fourth output coil 675 coiling around a second magnetic core 670. The first input coil 664 and the second input coil 663 of the first magnetic amplifier 66 respectively receive a first ac input 662 and a first dc signal input 661 and the third input coil 676 and the fourth input coil 674 of the second magnetic amplifier 67 respectively receive a second dc signal input 671 and a second ac input 672.

The first ac input 662 and the second ac input 672 can be respectively ac Lenz current flowing through a first reaction circuit of a first circuit and ac Lenz current flowing through a second reaction circuit of a second circuit. The first reaction circuit can or can not be the second reaction circuit and the first circuit can or can not be the second circuit. For example, if the first circuit is the second circuit and the first reaction circuit is the second reaction circuit then the first input coil 664 of the first magnetic amplifier 66 and the fourth input coil 674 of the second magnetic amplifier 67 can be coupled in series or in parallel in a same reaction circuit. FIG. 6m has shown two coupled magnetic amplifers embedded with the first switching circuit of FIG. 3a and it has also shown the first input coil 664 of the first magnetic amplifier 66 and the fourth input coil 674 of the second magnetic amplifier 67 are in parallel in the same reaction circuit and more detailed about the embodiment of FIG. 6m will be discussed later.

Another example, if the first circuit is the second circuit and the first reaction circuit is not the second reaction circuit then the first reaction circuit and the second reaction circuit could be in parallel. FIG. 6j has shown that the first reaction circuit is in parallel with the second reaction circuit and the first input coil 664 of the first magnetic amplifier 66 and the fourth input coil 674 of the second magnetic amplifier 67 are respectively in the first reaction circuit and the second reaction circuit of the first switching circuit. The first reaction circuit comprises the first input coil 664 of the first magnetic amplifier 66, the coupler 334, the first action/reaction isolation device 310 and the first damper 356 electrically connected in series with each other and the second reaction circuit comprises the fourth input coil 674 of the second magnetic amplifier 67, the second action/reaction isolation device 651 and the second damper 652 electrically connected in series with each other. FIG. 6j has shown two magnetic amplifers are embedded with the first switching circuit of FIG. 3a and the first switching circuit has two reaction circuits in parallel and more detailed about the embodiment of FIG. 6j will be discussed later.

For further another example, an ac output of any one output coil of the first magnetic amplifier 66 can be an ac input to the second magnetic amplifier 67 and a damper is needed to stabilize the ac output. And, an ac output of the output coil of the first magnetic amplifier 66 after being rectified by a rectifier can be the dc signal input to the second magnetic amplifier 67.

FIG. 6e has shown a damper 659 is placed in a loop formed by the second output coil 665 of the first magnetic amplifier 66 and the fourth input coil 674 of the second magnetic amplifier 67 and a rectifier 680 is used to rectify the output from the first output coil 666 as the dc signal input into the third input coil 676 of the second magnetic amplifier 67. FIG. 6e has also shown the damper 659, the second output coil 665 of the first magnetic amplifier 66 and the fourth input coil 674 of the second magnetic amplifier 67 electrically connected in series with each other.

The output of the rectifier 680 can be further filtered by a low-pass filter 644 to eliminate high frequency component as a better dc signal input to the second magnetic amplifier 67, which has been shown in FIG. 6f.

Further, a NDR device can be added to a dc loop formed by the rectifier 680, the filter 644 and the third input coil 676 of the second magnetic amplifier 67 to decrease the input resistance of the dc loop to obtain bigger gain. And further more, the dc loop formed by the filter 644 and the third input coil 676 of the second magnetic amplifier 67 can be positively fedback to the first dc signal input to increase its gain.

FIG. 6g has shown a dc loop formed by the rectifier 680, the filter 644, a NDR 643 and the third input coil 676 of the second magnetic amplifier 67 electrically connected in series with each other and a positive feedback from the dc loop to the first dc signal input as shown by a line 642.

The damper 659 and the rectifier 680 shown in FIG. 6g can be respectively realized by a PDR device and a NDR device connected in series and a Cockcroft-Walton generator (or CW generator in short) which is a voltage multiplier that can convert an ac electrical power from a low voltage level to a higher dc voltage level. FIG. 6h has shown the result and a Cockcroft-Walton generator 6801, a PDR 6591 and a first NDR 6592 are seen. The first magnetic amplifier 66 and the second magnetic amplifier 67 are connected in series so that the total gain of the two coupled magnetic amplifiers is the multiplication of each gain of each magnetic amplifier.

The two coupled magnetic amplifiers shown in FIG. 6h are embedded with the first switching circuit of FIG. 3a for more detailed description. FIG. 6i has shown the coupling. FIG. 6i has shown the first coil 301 of the first switching circuit is the second input coil 663 of the first magnetic amplifier 66 and the reaction circuit of the first switching circuit comprises the first input coil 664 of the first magnetic amplifier 66, the first damper 356, the coupler 334 and the first action/reaction isolation device 310 electrically serially connected with each other.

As revealed above, the waveform of the Lenz current flowing through the reaction circuit of the first switching circuit contains the frequency responses of the first switch 307 and the first coil 301 and the waveform of the Lenz current is modulated with the baseband waveform of the first PWM controller 309 so that the ac input and the dc signal input to the first magnetic amplifier 66 respectively through the first input coil 664 and the second input coil 663 of the first magnetic amplifier 66 has more chance to be synchronous to output maximum power.

FIG. 6j has shown a first switching circuit having a first reaction circuit and a second reaction circuit in parallel with each other and ac Lenz currents respectively flowing through the first reaction circuit and the second reaction circuit are respectively the ac inputs to the first magnetic amplifier 66 and the second magnetic amplifier 67. The first reaction circuit comprises the first input coil 664 of the first magnetic amplifier 66, the first damper 356 and the first action/reaction isolation device 310 electrically connected in series with each other. The second reaction circuit in parallel with the first reaction circuit comprises the fourth input coil 674 of the second magnetic amplifier 67, a second action/reaction isolation device 651 and a second damper 652 electrically connected in series with each other. FIG. 6j has shown the first reaction circuit, the second reaction circuit and the first coil 301 of the first switching circuit are in parallel with each other.

A plurality of coils in parallel in a same reaction circuit can respectively be the ac input coil to a plurality of the magnetic amplifiers. Using two magnetic amplifiers and the first switching circuit of FIG. 3a and shown in FIG. 6m, the fourth input coil 674 of the second magnetic amplifier 67 and the first input coil 664 of the first magnetic amplifier 66 are in the same reaction circuit and they are in parallel with each other. Please note that a positive feedback from the dc loop formed by the filter 644, a NDR 644 and the third input coil 676 of the second magnetic amplifier 67 to the first dc signal input as shown by a line 642.

The first, second and third switching circuits and the first, second and third high-voltage discharge circuits allow a plurality of coils in series with each other and the coils can be the dc input coil of the magnetic amplifier for receiving dc signal input. For example, using the switching circuit of FIG. 3a and shown in FIG. 6n, FIG. 6n has shown a first coil 301, a second coils 392 and a third coil 393 connected in series with each other and a reaction circuit comprising a damper 356 and an action/reaction isolation device 310 connected in series in parallel with the three coils 301, 392 and 393 which can be the coil coiling on the magnetic amplifier for receiving dc signal input. Two magnetic amplifiers and the first switching circuit of FIG. 3a will be used to demonstrate in more detailed description. FIG. 6o has shown the second input coil 663 of the first magnetic amplifier 66 and the third input coil 676 of the second magnetic amplifier 67 are electrically connected in series in the first switching circuit. FIG. 6o has also shown that the amplified first ac output of the first output coil 666 after the rectifier 680 also provides dc signal input to the second magnetic amplifier 67 and the amplified first ac output of the first output coil 666 after the rectifier 680 will be added to the dc from the dc power source 308, which means that the dc signal input into the second magnetic amplifier 67 will be larger than the dc signal input into the first magnetic amplifier 66 to promise the bigger gain of the second magnetic amplifier 67. FIG. 6o has shown that the fourth input coil 674 of the second magnetic amplifier 67 and the first input coil 664 of the first magnetic amplifier 66 are in parallel in the same reaction circuit and the second input coil 663 of the first magnetic amplifier 66 and the third input coil 676 of the second magnetic amplifier 67 are electrically connected in series in the first switching circuit.

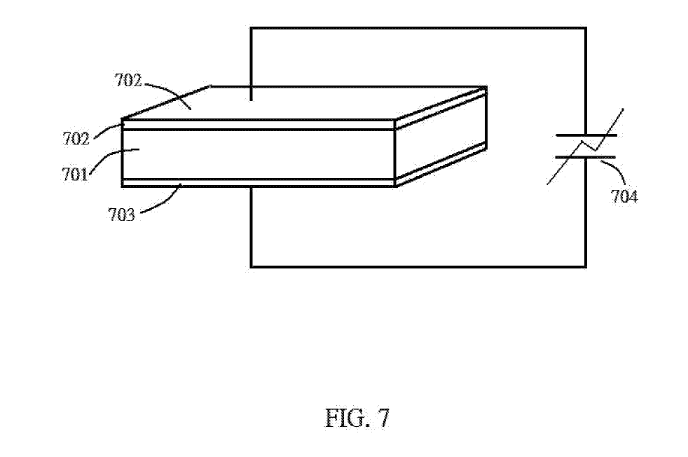

Two static magnets 667, 677 for providing static magnetic field respectively neighbor the first magnetic amplifier 66 and the second magnetic amplifier 67 for providing dc bias to the first magnetic amplifier 66 and the second magnetic amplifier 67. The two static magnets 667, 677 may not be needed if no such consideration. For high frequency condition, the known Eddy current induced on the surface of the static magnet could be the serious problem. The energy discharge capacitor of our previous invention can solve the so called Eddy current problem. FIG. 7 has shown a static magnet 701 with assumming Eddy current induced on a top side of it. For the purpose of convenience, Eddy current induced on a side of the static magnet is called acting side and a side without Eddy current is called non-acting side.

At least a portion of the acting side of the static magnet 701 is coated with a first NDR device 702 and at least a portion of the non-acting side of the static magnet 701 is coated with a second NDR device 703 and a loop is formed by the first NDR device 702, the second NDR device 703 and an energy discharge capacitor 704 electrically connected in series with each other. When Eddy current is induced on the acting side the resistance of the first NDR device 702 quickly decreases to generate bigger potential difference between the acting and non-acting sides in the loop resulting in more driving current flowing through the loop. The current will be dissipated by the energy discharge capacitor 704.

The number of the magnetic amplifiers coupled in series are not limited. For example, going back to the embodiment of FIG. 6i, the third output 678 and the fourth output 679 can respectively be an ac input and dc signal input to a third magnetic amplifier. A third magnetic amplifier coupled in series with the first and second magnetic amplifiers 66, 67 of FIG. 6i and FIG. 6h has been shown in FIG. 6k.

FIG. 6k has shown that the third output coil 675 and the fourth output coil 673 of the second magnetic amplifier 67 respectively provide an dc signal input and ac input to a third magnetic amplifier 68. A rectifier 6802, a filter 643 and a NDR device 642 are seen in a loop of the third output coil 675 of the second magnetic amplifier 67 and a fifth input coil 653 of the third magnetic amplifier 68, and a damper formed by a PDR device 6593 and a NDR device 6594 electrically connected in series are seen in a loop of the fourth output coil 673 of the second magnetic amplifier 67 and a sixth input coil 652 of the third magnetic amplifier 68. Please note again that the total gain of couplings is the multiplication of each gain of each magnetic amplifier.

The magnetic core of magnetic amplifier is not limited but a B-H saturable magnetic core is critical. The frequency response of magnetic amplifier can be very high so that a circuit with the magnetic amplifier can be a high speed power circuit good for driving high frequency loading.

The frequency of the output of the magnetic amplifier can be very high so that a frequency shifting for lowering its frequency may be needed for charging a lower speed battery or buffer. Based on the circuit of FIG. 6j, FIG. 6l has shown a frequency shifting 640 and a buffer or battery 639. The PDR device and NDR device are not limited, for example, the PDR device can be a PTC (Positive Temperature Coefficient) and the NDR can be a NTC (Negative Temperature Coefficient).The waveform output from the PWM controller in the present invention is not limited, for example, the waveform can be a positive-duty-control waveform or a negative-duty-control waveform.

1. A PWM controller operated by steps for m≧1:
checking if a first terminal signal appears at a first input terminal;
if no first terminal signal appears at the first input terminal, modulating a high-frequency waveform generated by a high-frequency-waveform generator with a m^{th} baseband waveform generated by a baseband generator;
if a first terminal signal appears at the first input terminal, stopping the high-frequency-waveform generator from generating high-frequency waveform, and 180°-phase-shifting the first terminal signal received at the first input terminal, and modulating the phase-shifted first terminal signal received at the first input terminal after the 180°-phase-shifting step with the m^{th} baseband waveform generated by the baseband generator;
checking if a second terminal signal appears at a second input terminal;
if the second terminal signal appears at the second input terminal, adjusting a duty cycle of the modulated waveform after the modulating step, and adjusting an m+1^{th} baseband waveform generated by the baseband generator, and outputting the duty-adjusted waveform after the duty-adjusted step; and
if no second terminal signal appears at the second input terminal, outputting the modulated waveform after the modulation step.

2. A PWM controller operated by steps for m≧1:
checking if a first terminal signal appears at a first input terminal;
if no first terminal signal appears at the first input terminal, modulating a high-frequency waveform generated by a high-frequency-waveform generator with a first baseband m^{th} waveform generated by a first baseband generator through a first modulator, and modulating the high-frequency waveform generated by the high-frequency-waveform generator with a second baseband m^{th} waveform generated by a second baseband generator through a third modulator;
if a first terminal signal appears at the first input terminal, stopping the high-frequency-waveform generator from generating high-frequency waveform, and 180°-phase-shifting the first terminal signal received at the first input terminal, and modulating the phase-shifted first terminal signal received at the first input terminal after the 180°-phase-shifting step with the first baseband m^{th} waveform generated by the first baseband generator through a second modulator, and modulating the phase-shifted first terminal signal received at the first input terminal after the 180°-phase-shifting step with the second baseband m^{th} waveform generated by the second baseband generator through a fourth modulator;
checking if a second terminal signal appears at the second input terminal;
if a second terminal signal appears at the second input terminal, adjusting a duty cycle of the modulated waveforms either out from the first modulator or the second modulator and outputting the duty-adjusted waveform after the duty-adjusted step, and adjusting a duty cycle of the modulated waveforms either out from the third modulator or the fourth modulator and outputting the duty-adjusted waveform after the duty-adjusted step, and adjusting a first baseband m+1^{th} waveform generated by the first baseband generator and a second baseband m+1^{th} waveform generated by the second baseband generator; and
if no second terminal signal appears at the second input terminal, outputting the modulated waveforms either out from the first modulator or the second modulator, and outputting the modulated waveforms either out from the third modulator or the fourth modulator.

3. A switching circuit, comprising:
a dc power source;
a switch;
a first coil, wherein the dc power source, the first coil and the switch electrically connected in series with each other by the sequence;
a reaction circuit in parallel with the first coil, wherein the reaction circuit allows ac Lenz current to flow through the reaction circuit and prohibits dc from the dc power source from flowing through the reaction circuit, and the reaction circuit comprises a damper, an action/reaction isolation circuit and a coupler electrically connected in series with each other, and the action/reaction isolation device is for allowing an ac Lenz current produced by the switch in open state to flow through the reaction circuit and prohibiting a dc from the dc power source from flowing through the reaction circuit, and the damper is for stabilizing the ac Lenz current flowing through the reaction circuit, and the coupler is for coupling a waveform of the ac Lenz current flowing through the reaction circuit; and
A PWM controller operated by steps for m≧1:
checking if a first terminal signal appears at a first input terminal, wherein the coupler couples the waveform of the ac Lenz current flowing through the reaction circuit into the first input terminal;
if no first terminal signal appears at the first input terminal, modulating a high-frequency waveform generated by a high-frequency-waveform generator with a mth baseband waveform generated by a baseband generator;
if a first terminal signal appears at the first input terminal, stopping the high-frequency-waveform generator from generating high-frequency waveform, and 180°-phase-shifting the first terminal signal received at the first input terminal, and modulating the phase-shifted first terminal signal received at the first input terminal after the 180°-phase-shifting step with the mth baseband waveform generated by the baseband generator;
checking if a second terminal signal appears at a second input terminal, wherein the second terminal signal is a signal from an emergency procedure, a signal from manual control or a signal from sensor such as voltage sensor, current sensor, thermal sensor or chemical sensor;
if the second terminal signal appears at the second input terminal, adjusting a duty cycle of the modulated waveform after the modulating step and outputting the duty-adjusted waveform after the duty-adjusted step for controlling the switch, and adjusting an m+1^{th} baseband waveform generated by the baseband generator; and
if no second terminal signal appears at the second input terminal, outputting the modulated waveform after the modulating step for controlling the switch.

4. The switching circuit of claim 3, wherein the dc power source is a capacitor, a battery, a solar cell or a fuel cell, and the action/reaction isolation device is a capacitor, and the coupler is a transformer, and the damper comprises a PDR device and a NDR device electrically connected in series, and the switch is a power transistor.

5. A switching circuit, comprising:
a dc power source;
a first switch;
a second switch;
a first coil, wherein the dc power source, the second switch, the first coil and the first switch electrically connect in series with each other by the sequence;
a reaction circuit in parallel with the first coil, wherein the reaction circuit allows ac Lenz current to flow through the reaction circuit and prohibits dc from the dc power source from flowing through the reaction circuit, and the reaction circuit comprises a damper, an action/reaction isolation circuit and a coupler electrically connected in series with each other, and the action/reaction isolation device is for allowing an ac Lenz current produced by the switch in open state to flow through the reaction circuit and prohibiting a dc from the dc power source from flowing through the reaction circuit, and the damper is for stabilizing the ac Lenz current flowing through the reaction circuit, and the coupler is for coupling a waveform of the ac Lenz current flowing through the reaction circuit; and
A PWM controller operated by steps for m≧1:
checking if a first terminal signal appears at a first input terminal, wherein the coupler couples the waveform of the ac Lenz current flowing through the reaction circuit into the first input terminal;
if no first terminal signal appears at the first input terminal, modulating a high-frequency waveform generated by a high-frequency-waveform generator with a first baseband m^{th} waveform generated by a first baseband generator through a first modulator, and modulating the high-frequency waveform generated by the high-frequency-waveform generator with a second baseband m^{th} waveform generated by a second baseband generator through a third modulator;
if a first terminal signal appears at the first input terminal, stopping the high-frequency-waveform generator from generating high-frequency waveform, and 180°-phase-shifting the first terminal signal received at the first input terminal, and modulating the phase-shifted first terminal signal received at the first input terminal after the 180°-phase-shifting step with the first baseband mth waveform generated by the first baseband generator through a second modulator, and modulating the phase-shifted first terminal signal received at the first input terminal after the 180°-phase-shifting step with the second baseband m^{th} waveform generated by the second baseband generator through a fourth modulator;
checking if a second terminal signal appears at the second input terminal, wherein the second terminal signal is a signal from an emergency procedure, a signal from manual control or a signal from sensor such as voltage sensor, current sensor, thermal sensor or chemical sensor;
if a second terminal signal appears at the second input terminal, adjusting a duty cycle of the modulated waveforms either out from the first modulator or the second modulator and outputting the duty-adjusted waveform after the duty-adjusted step for controlling the first switch, and adjusting a duty cycle of the modulated waveforms either out from the third modulator or the fourth modulator and outputting the duty-adjusted waveform after the duty-adjusted step for controlling the second switch, and adjusting a first baseband m+1^{th} waveform generated by the first baseband generator and a second baseband m+1^{th} waveform generated by the second baseband generator; and
if no second terminal signal appears at the second input terminal, outputting the modulated waveforms either out from the first modulator or the second modulator for controlling the first switch, and outputting the modulated waveforms either out from the third modulator or the fourth modulator for controlling the second switch.

6. The switching circuit of claim 5, wherein the dc power source is a capacitor, a battery, a solar cell or a fuel cell, and the action/reaction isolation device is a capacitor, and the coupler is a transformer, and the damper comprises a PDR device and a NDR device electrically connected in series, and the first switch and the second switch are power transistors.

7. A switching circuit, comprising:
a dc power source;
a switch;
a first coil, wherein the dc power source, the first coil and the switch electrically connected in series with each other by the sequence;
a reaction circuit in parallel with the first coil, wherein the reaction circuit comprises a damper, an action/reaction isolation circuit and a coupler electrically connected in series with each other, and the action/reaction isolation device is for allowing an ac Lenz current produced by the switch in open state to flow through the reaction circuit and prohibiting a dc from the dc power source from flowing the reaction circuit, and the damper is for stabilizing the ac Lenz current flowing through the reaction circuit; and
a PWM controller for controlling the switch.

8. The switching circuit of claim 7, wherein the dc power source is a capacitor, a battery, a solarcell or a fuel cell, and the action/reaction isolation device is a capacitor, and the damper comprises a PDR device and a NDR device electrically connected in series, and the switch is a power transistor.

9. The switching circuit of claim 3, further comprising an open discharge gap having a first terminal and a second terminal and a second coil having a third terminal and a fourth terminal, wherein the second coil forms a transformer with the first coil for boosting voltage, and the first terminal electrically connects to the third terminal and the second terminal electrically connects to a low side such as the ground, and the fourth terminal electrically connects the high side or the low side of the first coil.

10. The switching circuit of claim 9, further comprising an ion-release device, wherein the ion-release device is disposed by the open discharge gap under the influence of a high voltage built at the open discharge gap, and the ion-release device releases ions under the influence of the high voltage.

11. The switching circuit of claim 9, wherein a waste is disposed by the open discharge gap under the influence of a high voltage built at the open discharge gap, and the high voltage built at the open discharge gap powders the waste.

12. The switching circuit of claim 9, further comprising a welding device, wherein the welding device is disposed by the open discharge gap under the influence of a high voltage built at the open discharge gap, and the welding device is welded to another matter under the influence of the high voltage.

13. The switching circuit of claim 9, further comprising a H₂O-containing electrolyzer having a positive electrode and a negative electrode, wherein the first terminal and the second terminal of the open discharge gap are respectively electrically connected to the positive electrode and the negative electrode of the H₂O-containing electrolyzer.

14. The switching circuit of claim 5, further comprising an open discharge gap having a first terminal and a second terminal and a second coil having a third terminal and a fourth terminal, wherein the second coil forms a transformer with the first coil for boosting voltage, and the first terminal electrically connects to the third terminal and the second terminal electrically connects to a low side such as the ground, and the fourth terminal electrically connects the high side or the low side of the first coil.

15. The switching circuit of claim 14, further comprising an ion-release device, wherein the ion-release device is disposed by the open discharge gap under the influence of a high voltage built at the open discharge gap, and the ion-release device releases ions under the high voltage.

16. The switching circuit of claim 14, wherein a waste is disposed by the open discharge gap under the influence of a high voltage built at the open discharge gap, and the high voltage built at the open discharge gap powders the waste.

17. The switching circuit of claim 14, further comprising a welding device, wherein the welding device is disposed by the open discharge gap under the influence of a high voltage built at the open discharge gap, and the welding device is welded to another matter under the high voltage.

18. The switching circuit of claim 14, further comprising a H₂O-containing electrolyzer having a positive electrode and a negative electrode, wherein the first terminal and the second terminal of the open discharge gap are respectively electrically connected to the positive electrode and the negative electrode of the H₂O-containing electrolyzer.

19. The switching circuit of claim 7, further comprising an open discharge gap having a first terminal and a second terminal and a second coil having a third terminal and a fourth terminal, wherein the second coil forms a transformer with the first coil for boosting voltage, and the first terminal electrically connects to the third terminal and the second terminal electrically connects to a low side such as the ground, and the fourth terminal electrically connects the high side or the low side of the first coil.

20. The switching circuit of claim 19, further comprising an ion-release device, wherein the ion-release device is disposed by the open discharge gap under the influence of a high voltage built at the open discharge gap, and the ion-release device releases ions under the high voltage.

21. The switching circuit of claim 19, wherein a waste is disposed by the open discharge gap under the influence of a high voltage built at the open discharge gap, and the high voltage built at the open discharge gap powders the waste.

22. The switching circuit of claim 19, further comprising a welding device, wherein the welding device is disposed by the open discharge gap under the influence of a high voltage built at the open discharge gap, and the welding material is welded to another matter under the high voltage.

23. The switching circuit of claim 19, further comprising a H₂O-containing electrolyzer having a positive electrode and a negative electrode, wherein the first terminal and the second terminal of the open discharge gap are respectively electrically connected to the positive electrode and the negative electrode of the H₂O-containing electrolyzer.

24. A magnetic amplifier, comprising:
a first magnetic core;
a first coil coiling around the first magnetic core for receiving ac Lenz current flowing through a first reaction circuit, wherein the first reaction circuit comprises the first coil, a first damper and a first action/reaction isolation device electrically connected in series with each other, and the first action/reaction isolation device is for allowing an ac Lenz current to flow through the first reaction circuit but prohibiting dc from flowing through the first reaction circuit, and the first damper is for stabilizing the ac Lenz current flowing through the first reaction circuit;
a second coil coiling around the first magnetic core for receiving dc signal input; and
a third coil coiling around the first magnetic core for outputing a first ac output.

25. The magnetic amplifier of claim 24, further comprising a first static magnet neighboring the first magnetic core for providing dc bias.

26. The magnetic amplifier of claim 25, wherein the first magnetic core is a B-H saturable magnetic core, and the first damper comprises a first PDR device and a first NDR device electrically connected in series, and the first action/reaction isolation device is a capacitor or a diode.

27. The magnetic amplifier of claim 26, further comprising:
a second magnetic core;
a fourth coil coiling around the first magnetic core for receiving ac Lenz current flowing through a second reaction circuit, wherein the second reaction circuit comprises the fourth coil, a second damper and a second action/reaction isolation device electrically connected in series with each other, and the second action/reaction isolation device is for allowing an ac Lenz current to flow through the second reaction circuit but prohibiting dc from flowing through the second reaction circuit, and the second damper is for stabilizing the ac Lenz current flowing through the second reaction circuit;
a fifth coil coiling around the second magnetic core for receiving dc signal input, wherein the first ac output of the third coil is rectified by a rectifier, and a dc loop is formed by the rectifier and the fifth coil electrically connected in series; and
a sixth coil coiling around the magnetic core for outputting a second ac output.

28. The magnetic amplifier of claim 27, further comprising a second static magnet neighboring the second magnetic core for providing dc bias, wherein the second magnetic core is a B-H saturable magnetic core, and the second damper comprises a second PDR device and a second NDR device electrically connected in series, and the second action/reaction isolation device is a capacitor or a diode.

29. The magnetic amplifier of claim 28, further comprising a low-pass filter for filtering out the high-frequency component in the dc loop, and the rectifier, the low-pass filter and the fifth coil are electrically connected in series.

30. The magnetic amplifier of claim 29, further comprising a third NDR device for decreasing the input resistance of the dc loop, wherein the rectifier, the low-pass filter, the third NDR device and the fifth coil are electrically connected in series with each other, and the dc loop is electrically connected to the second coil as a positive feedback.

31. The magnetic amplifier of claim 30, wherein the first reaction circuit is the second reaction circuit, and the first damper is the second damper, and the first action/reaction isolation device is the second action/reaction isolation device, and the first coil and the fourth coil are in parallel.

32. The magnetic amplifier of claim 31, wherein the fifth coil and the second coil are electrically connected in series and a dc flows through the fifth coil and the second coil.

33. The magnetic amplifier of claim 32, further comprising a first energy discharge capacitor and a second energy discharge capacitor, wherein a side induced an Eddy current of the first static magnet and another side without Eddy current of the first static magnet are respectively coated with a fourth NDR device and a fifth NDR device, and a first loop is formed by the fourth NDR device, the fifth NDR device and the first energy discharge capacitor electrically connected in series with each other, and a side induced an Eddy current of the second static magnet and another side without Eddy current of the second static magnet are respectively coated with a sixth NDR device and a seventh NDR device, and a second loop is formed by the sixth NDR device, the seventh NDR device and the second energy discharge capacitor electrically connected in series with each other.
